(19) United States
(12) Patent Application Publication
(10) Pub. No.: US 2005/0205910 A1
(43) Pub. Date: Sep. 22, 2005

(54) Semiconductor device having ferroelectric memory and manufacturing method of the semiconductor device

(76) Inventors: Yoshinori Kumura, Yokohama-shi (JP); Hiroyuki Kanaya, Yokohama-shi (JP); Tohru Ozaki, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/960,029

(22) Filed: Oct. 8, 2004

(30) Foreign Application Priority Data
Mar. 16, 2004 (JP) 2004-074457

(51) Int. Cl. H01L 29/76; H01L 21/00

(52) U.S. Cl. 257/295; 257/758; 438/3; 438/622

(57) ABSTRACT

A transistor including a source/drain region is formed on a semiconductor substrate. A plug electrode is formed on the source/drain region. A conductive film is formed on the plug electrode. A first insulation film is formed on the conductive film. A lower electrode is formed on the first insulation film, and electrically connected to the conductive film formed on the plug electrode. A ferroelectric film is formed on the lower electrode. An upper electrode is formed on the ferroelectric film.

### CROSS-REFERENCE TO RELATED APPLICATIONS

This application is based upon and claims the benefit of priority from prior Japanese Patent Application No. 2004-074457, filed Mar. 16, 2004, the entire contents of which are incorporated herein by reference.

### BACKGROUND OF THE INVENTION

1. Field of the Invention

This invention relates to a semiconductor device having a ferroelectric memory and a manufacturing method of the semiconductor device.

2. Description of the Related Art

Recently, a highly integrated ferroelectric memory has employed a COP (capacitor on plug) structure having a ferroelectric capacitor formed on a plug electrode (as disclosed in, for example, Jpn. Pat. Appln. KOKAI Publication No. 2003-51583). In the conventional COP structure, a conductive oxygen barrier film having conductivity and shutting out penetration of oxygen has been arranged on a contact plug connected to source/drain of a transistor, and a lower electrode, a ferroelectric film and an upper electrode forming a ferroelectric capacitor have been formed immediately above the barrier film.

Incidentally, to recover from process damage of the ferroelectric capacitor having such a structure, oxygen annealing needs to be performed at a high temperature. For this reason, even in the oxygen annealing at a high temperature, the structure of the conductive oxygen barrier film capable of shutting out penetration of oxygen into the contact plug needs to be optimized.

In the structure having the lower electrode of the ferroelectric capacitor arranged immediately above the conductive oxygen barrier film, however, if the structure of the conductive oxygen barrier film is optimized, a problem arises that ferroelectric capacitor characteristics are deteriorated due to diffusion of a material of the conductive oxygen barrier film into the ferroelectric capacitor and stress generated between the conductive oxygen barrier film and the lower electrode. For this reason, a semiconductor device having an optimum conductive oxygen barrier film and preferable ferroelectric capacitor characteristics and a manufacturing method of the semiconductor device can hardly be achieved.

### BRIEF SUMMARY OF THE INVENTION

According to an aspect of the present invention, there is provided a semiconductor device comprising a transistor formed on a semiconductor substrate, including a source/drain region, a plug electrode formed on the source/drain region, a conductive film formed on the plug electrode, a first insulation film formed on the conductive film, a lower electrode formed on the first insulation film, the lower electrode being electrically connected to the conductive film formed on the plug electrode, a ferroelectric film formed on the lower electrode, and an upper electrode formed on the ferroelectric film.

According to another aspect of the present invention, there is provided a semiconductor device comprising a first source/drain region formed on a surface region of a semiconductor substrate, a second source/drain region formed on the surface region of the semiconductor substrate, separately from the first source/drain region, a first gate insulation film formed on the semiconductor substrate between the first source/drain region and the second source/drain region, a first gate electrode formed on the first gate insulation film, an interlayer insulation film formed on the semiconductor substrate so as to cover the first source/drain region, the second source/drain region, and the first gate electrode, a plug electrode formed in the interlayer insulation film on the first source/drain region and electrically connected to the first source/drain region, a conductive film formed on the plug electrode and electrically connected to the plug electrode, a first insulation film formed on the conductive film, a lower electrode formed on the first insulation film, a first ferroelectric film and a second ferroelectric film both formed on the lower electrode, a first upper electrode formed on the first ferroelectric film and electrically connected to the second source/drain region, and a second upper electrode formed on the second ferroelectric film.

According to still another aspect of the present invention, there is provided a method of manufacturing a semiconductor device, comprising forming a transistor including a gate insulation film, a gate electrode and a source/drain region on a semiconductor substrate, forming an interlayer insulation film on the semiconductor substrate on which the transistor is formed, forming a contact plug electrically connected to the source/drain region, in the interlayer insulation film on the source/drain region, forming a conductive film on the contact plug and the interlayer insulation film, forming a first insulation film on the conductive film, forming a lower electrode on the first insulation film, forming a ferroelectric film on the lower electrode, and forming an upper electrode on the ferroelectric film.

### BRIEF DESCRIPTION OF THE SEVERAL VIEWS OF THE DRAWING

FIG. 1 is a cross-sectional view showing a multi-layer film used in a semiconductor device according to first to fifth embodiments of the present invention;

FIG. 2 is a cross-sectional view showing a semiconductor device including a ferroelectric memory, according to the first embodiment of the present invention;

FIG. 3 is a cross-sectional view showing the semiconductor device including the TC-parallel unit serial-connection type ferroelectric memory, according to the first embodiment;

FIG. 4 is a cross-sectional view showing a semiconductor device including a ferroelectric memory, according to the second embodiment of the present invention;

FIG. 5 is a cross-sectional view showing the semiconductor device including the TC-parallel unit serial-connection type ferroelectric memory, according to the second embodiment;

FIG. 6 is a cross-sectional view showing the semiconductor device including the TC-parallel unit serial-connection type ferroelectric memory, according to a modified example of the second embodiment;

FIG. 7 is a cross-sectional view showing a semiconductor device including a ferroelectric memory, according to the third embodiment of the present invention;

FIG. 8 is a cross-sectional view showing the semiconductor device including the TC-parallel unit serial-connection type ferroelectric memory, according to the third embodiment;

FIG. 9 is a cross-sectional view showing a semiconductor device including a ferroelectric memory, according to the fourth embodiment of the present invention;

FIG. 10 is a cross-sectional view showing the semiconductor device including the TC-parallel unit serial-connection type ferroelectric memory, according to the fourth embodiment;

FIG. 11 is a cross-sectional view showing a semiconductor device including a ferroelectric memory, according to the fifth embodiment of the present invention;

FIG. 12 is a cross-sectional view showing the semiconductor device including the TC-parallel unit serial-connection type ferroelectric memory, according to the fifth embodiment;

FIG. 13 is a cross-sectional view showing multi-layer films used in a semiconductor device according to sixth to tenth embodiments of the present invention;

FIG. 14 is a cross-sectional view showing a semiconductor device including a ferroelectric memory, according to the sixth embodiment of the present invention;

FIG. 15 is a cross-sectional view showing the semiconductor device including the TC-parallel unit serial-connection type ferroelectric memory, according to the sixth embodiment;

FIG. 16 is a cross-sectional view showing a semiconductor device including a ferroelectric memory, according to the seventh embodiment of the present invention;

FIG. 17 is a cross-sectional view showing the semiconductor device including the TC-parallel unit serial-connection type ferroelectric memory, according to the seventh embodiment;

FIG. 18 is a cross-sectional view showing the semiconductor device including the TC-parallel unit serial-connection type ferroelectric memory, according to a modified example of the seventh embodiment;

FIG. 19 is a cross-sectional view showing a semiconductor device including a ferroelectric memory, according to the eighth embodiment of the present invention;

FIG. 20 is a cross-sectional view showing the semiconductor device including the TC-parallel unit serial-connection type ferroelectric memory, according to the eighth embodiment;

FIG. 21 is a cross-sectional view showing a semiconductor device including a ferroelectric memory, according to the ninth embodiment of the present invention;

FIG. 22 is a cross-sectional view showing the semiconductor device including the TC-parallel unit serial-connection type ferroelectric memory, according to the ninth embodiment;

FIG. 23 is a cross-sectional view showing a semiconductor device including a ferroelectric memory, according to the tenth embodiment of the present invention;

FIG. 24 is a cross-sectional view showing the semiconductor device including the TC-parallel unit serial-connection type ferroelectric memory, according to the tenth embodiment;

FIGS. 25 and 26 are cross-sectional views showing the semiconductor device including the ferroelectric memory according to the first embodiment as shown in FIG. 2, in first and second steps of a manufacturing method of the semiconductor device;

FIGS. 27 and 28 are cross-sectional views showing the semiconductor device including the ferroelectric memory according to the second embodiment as shown in FIG. 4, in first and second steps of a manufacturing method of the semiconductor device;

FIGS. 29 to 31 are cross-sectional views showing the semiconductor device including the ferroelectric memory according to the third embodiment as shown in FIG. 7, in first to third steps of a manufacturing method of the semiconductor device;

FIGS. 32 to 34 are cross-sectional views showing the semiconductor device including the ferroelectric memory according to the fourth embodiment as shown in FIG. 9, in first to third steps of a manufacturing method of the semiconductor device; and

FIGS. 35 to 37 are cross-sectional views showing the semiconductor device including the ferroelectric memory according to the fifth embodiment as shown in FIG. 11, in first to third steps of a manufacturing method of the semiconductor device.

### DETAILED DESCRIPTION OF THE INVENTION

A semiconductor device including a ferroelectric memory according to the embodiments of the present invention will be explained below with reference to the accompanying drawings. Like elements are denoted throughout the drawings by like or similar reference numbers.

First, a structure of a multilayer film used in a ferroelectric memory according to first to fifth embodiments of the present invention will be explained.

FIG. 1 is a cross-sectional view showing a multi-layer film used in a semiconductor device according to the first to fifth embodiments.

A conductive oxygen barrier film 13 is formed on a contact plug 12 embedded in an interlayer insulation film 11. The conductive oxygen barrier film 13 has conductivity and shuts out penetration of oxygen. In other words, the conductive oxygen barrier film 13 has a function of preventing oxygen from reaching the contact plug 12. The conductive oxygen barrier film 13 is formed of materials including, for example, iridium (Ir), iridium oxide (IrO₂), ruthenium (Ru), ruthenium oxide (RuO₂) or the like.

An insulating buffer layer 14 is formed on the conductive oxygen barrier film 13. A lower electrode 15 is formed on the buffer layer 14. A ferroelectric film 16 is formed on the lower electrode 15. An upper electrode 17 is formed on the ferroelectric film 16. The buffer layer 14 has a function of preventing the materials contained in the conductive oxygen barrier film 13 from diffusing to the lower electrode 15 and the ferroelectric film 16, and a function of preventing oxygen from reaching the contact plug 12. The buffer layer 14 also has a function of reducing stress generated between the conductive oxygen barrier film 13 and the lower electrode 15. The buffer layer 14 is composed of a silicon oxide film (SiO₂) such as TEOS or a silicon nitride film (SiN), or formed of materials including SiON, alumina (Al₂O₃), PZT, titanium oxide (TiO₂), STO or the like.

### First Embodiment

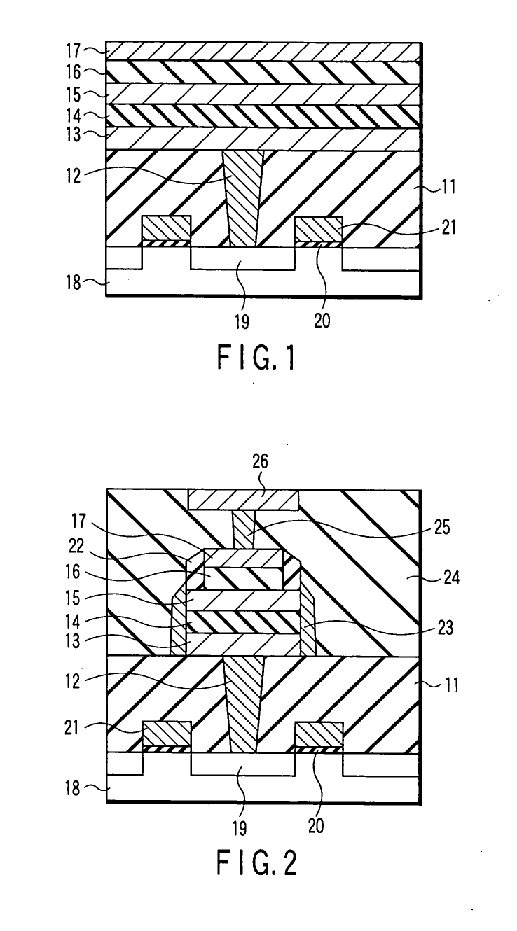

FIG. 2 is a cross-sectional view showing a semiconductor device including a ferroelectric memory, according to the first embodiment.

Source/drain regions 19 are formed in a surface region of a silicon semiconductor substrate 18. A gate insulation film 20 is formed on the semiconductor substrate 18 serving as a channel region between the source/drain regions 19. A gate electrode 21 is formed on the gate insulation film 20. A cell transistor is composed of the source/drain regions 19, the gate insulation film 20, the gate electrode 21 and the channel region.

The interlayer insulation film 11 is formed on the source/drain regions 19 and the gate electrode 21. The contact plug (plug electrode) 12 embedded in the interlayer insulation film 11 is formed on the source/drain regions 19. The contact plug 12 is electrically connected to the source/drain regions 19.

The conductive oxygen barrier film 13 is formed on the contact plug 12 and electrically connected to the contact plug 12. The conductive oxygen barrier film 13 has conductivity and has a function of shutting out penetration of oxygen, especially preventing oxygen from reaching the contact plug 12 and the contact plug 12 from being oxidized during the heat treatment in an oxygen atmosphere. The conductive oxygen barrier film 13 is formed of materials including, for example, Ir, IrO₂, Ru, RuO₂ or the like as described above.

The insulating buffer layer 14 is formed on the conductive oxygen barrier film 13. The lower electrode 15 is formed on the buffer layer 14. The ferroelectric film 16 is formed on the lower electrode 15. The upper electrode 17 is formed on the ferroelectric film 16. A ferroelectric capacitor is composed of the lower electrode 15, the ferroelectric film 16 and the upper electrode 17. As described above, the buffer layer 14 has a function of preventing the materials contained in the conductive oxygen barrier film 13 from diffusing to the lower electrode 15 and further to the ferroelectric film 16, and a function of preventing oxygen from reaching the contact plug 12 and the contact plug 12 from being oxidized during the heat treatment in an oxygen atmosphere similarly to the conductive oxygen barrier film 13. The buffer layer 14 also has a function of reducing difference between stresses generated on the conductive oxygen barrier film 13 and the lower electrode 15 during the heat treatment. The buffer layer 14 is formed of materials containing SiO₂ such as TEOS or the like, SiN, SiON, Al₂O₃, PZT, TiO₂, STO or the like.

Sidewall insulation films 22 are formed on side surfaces of the ferroelectric film 16, side surfaces of the upper electrode 17, and on the lower electrode 15. The sidewall insulation films 22 are composed of a silicon oxide film such as TEOS, or formed of materials containing Al₂O₃ or the like. Sidewall conductive films 23 are formed on side surfaces of the conductive oxygen barrier film 13, side surfaces of the buffer layer 14, and side surfaces of the lower electrode 15. The sidewall conductive films 23 are formed of materials containing platinum (Pt) or the like. The conductive oxygen barrier film 13 and the lower electrode 15 are electrically connected to each other by the sidewall conductive films 23. The sidewall insulation films 22 have a function of preventing the lower electrode 15 and the upper electrode 17 from being electrically connected by the sidewall conductive films 23.

An interlayer insulation film 24 is formed on the upper electrode 17, the sidewall insulation films 22, the sidewall conductive films 23 and the interlayer insulation film 11. A contact plug 25 embedded in the interlayer insulation film 24 is formed on the upper electrode 17. The contact plug 25 is electrically connected to the upper electrode 17. A wiring layer 26 electrically connected to the contact plug 25 is formed on the contact plug 25.

In the semiconductor device thus formed, diffusion of the chemical elements contained in the conductive oxygen barrier film 13 into the lower electrode 15 or the ferroelectric film 16 can be prevented by arranging the buffer layer 14 between the conductive oxygen barrier film 13 and the lower electrode 15, and deterioration of the lower electrode 15 and the ferroelectric film 16 can be thereby prevented. In addition, the difference between the stresses generated on the conductive oxygen barrier film 13 and the lower electrode 15 can be reduced during the heat treatment, and defectiveness such as degradation of close contact between the conductive oxygen barrier film 13 and the lower electrode 15 can be prevented. Moreover, as the materials of the conductive oxygen barrier film 13 can be optimized without considering diffusion into the lower electrode 15 or the ferroelectric film 16, oxidation of the contact plug can be certainly prevented. Thus, deterioration of characteristics and reduction of reliability in the ferroelectric capacitor can be restricted.

For example, the conductive oxygen barrier film 13 may be formed of a multilayer film of Ir and IrO₂, the buffer layer 14 may contain Al₂O₃, and the lower electrode 15 may contain Pt. In this case, oxygen annealing needs to be preformed at a high temperature, for recovery from process damage of the ferroelectric capacitor. Ir contained in the conductive oxygen barrier film 13 diffuses in the high-temperature oxygen annealing. However, as diffused Ir is blocked by the buffer layer (Al₂O₃) 14, Ir does not reach the lower electrode 15 or the ferroelectric film 16. For this reason, formation of an alloy of Pt contained in the lower electrode 15 with Ir, and deterioration of the lower electrode 15 and ferroelectric film 16 can be prevented.

In addition, as intruding oxygen is blocked by the conductive oxygen barrier film (Ir) 13, oxygen does not reach the contact plug 12 in the high-temperature oxygen annealing. For this reason, oxidization of the contact plug 12 can be prevented in the high-temperature oxygen annealing.

There is great difference between the stress generated on Ir and IrO₂ of the conductive oxygen barrier film 13 and the stress generated on Pt of the lower electrode 15, in the high-temperature oxygen annealing. For this reason, contact between the conductive oxygen barrier film 13 and the lower electrode 15 may be decreased. However, the difference in stress therebetween can be reduced by arranging the buffer layer (Al₂O₃) 14 between the conductive oxygen barrier film (Ir, IrO₂) 13 and the lower electrode (Pt) 15. The decrease in contact between the conductive oxygen barrier film 13 and the lower electrode 15 can be thereby restricted.

In this embodiment, the amount of charge which the ferroelectric capacitor can originally store can be therefore maintained without reduction. In other words, the ferroelectric capacitor the ferroelectric capacitor can maintain the amount of polarization which it originally has. For example, the ferroelectric capacitor of a predetermined shape in a structure having the buffer layer 14 between the conductive oxygen barrier film 13 and the lower electrode 15 can store the amount of charge of approximately 35 μC/cm², which it can originally store. However, the ferroelectric capacitor of a predetermined shape in a structure having no buffer layer 14 therebetween can store the amount of charge of approximately 25 μC/cm² only as the materials contained in the conductive oxygen barrier film 13 diffuse into the lower electrode 15 and the ferroelectric film 16 and deteriorate them. Thus, if the amount of charge (polarization) stored in the ferroelectric capacitor can be maintained without reduction, writing and reading of “1” and “0” can be performed easily with high reliability, in the memory including the ferroelectric capacitor.

Next, an example of applying the structure of the first embodiment shown in FIG. 2 to a TC-parallel unit serial-connection type ferroelectric memory will be explained. In the ferroelectric memory of this type, each of a lower electrode and an upper electrode of the ferroelectric capacitor (C) is connected between the source and drain of a cell transistor (T), as a unit cell, and a plurality of unit cells are connected in series.

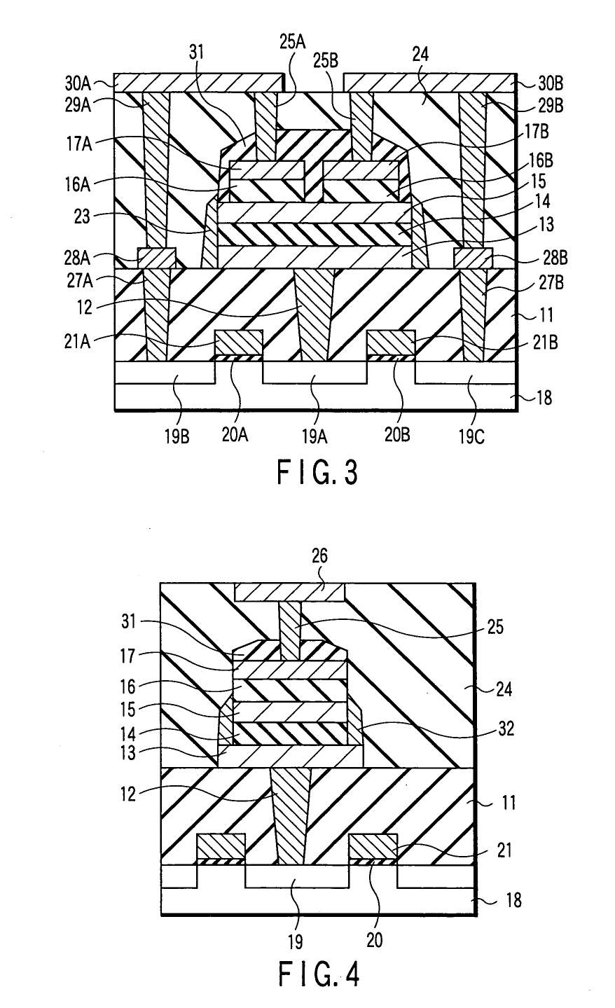

FIG. 3 is a cross-sectional view showing the semiconductor device including the TC-parallel unit serial-connection type ferroelectric memory, according to the first embodiment.

Source/drain regions 19A, 19B and 19C are formed on the surface of the silicon semiconductor substrate 18. A gate insulation film 20A is formed on the semiconductor substrate 18 between the source/drain regions 19A and 19B. A gate insulation film 20B is formed on the semiconductor substrate 18 between the source/drain regions 19A and 19C. Gate electrodes 21A and 21B are formed on the gate insulation films 20A and 20B, respectively. The interlayer insulation film 11 is formed on the source/drain regions 19A, 19B and 19C and on the gate electrodes 20A and 20B. The contact plug 12 embedded in the interlayer insulation film 11 is formed on the source/drain region 19A.

The conductive oxygen barrier film 13 is formed on the contact plug 12. The conductive oxygen barrier film 13 is electrically connected to the contact plug 12. The conductive oxygen barrier film 13 is formed of materials including, for example, Ir, IrO₂, Ru, RuO₂ or the like as described above. The conductive oxygen barrier film 13 has a function of preventing oxygen from reaching the contact plug 12 and the contact plug 12 from being oxidized during the heat treatment in the oxygen atmosphere.

The insulating buffer layer 14 is formed on the conductive oxygen barrier film 13. The lower electrode 15 is formed on the buffer layer 14. Ferroelectric films 16A and 16B are formed on the lower electrode 15 and separated from each other. An upper electrode 17A is formed on the ferroelectric film 16A. An upper electrode 17B is formed on the ferroelectric film 16B. A first ferroelectric capacitor is composed of the lower electrode 15, the ferroelectric film 16A and the upper electrode 17A. A second ferroelectric capacitor is composed of the lower electrode 15, the ferroelectric film 16B and the upper electrode 17B. As described above, the buffer layer 14 has a function of preventing the materials contained in the conductive oxygen barrier film 13 from diffusing to the lower electrode 15 and further to the ferroelectric films 16A and 16B, and a function of preventing oxygen from reaching the contact plug 12 and the contact plug 12 from being oxidized during the heat treatment in an oxygen atmosphere similarly to the conductive oxygen barrier film 13.

An insulation film 31 is formed on side surfaces of the ferroelectric films 16A and 16B, top surfaces and side surfaces of the upper electrodes 17A and 17B, and on the lower electrode 15. Moreover, sidewall conductive films 23 are formed on the side surfaces of the conductive oxygen barrier film 13, the side surfaces of the buffer layer 14, and the side surfaces of the lower electrode 15. The conductive oxygen barrier film 13 and the lower electrode 15 are electrically connected to each other by the sidewall conductive films 23. The insulation film 31 has a function of preventing the lower electrode 15 and the upper electrodes 17A and 17B from being electrically connected by the sidewall conductive films 23.

The interlayer insulation film 24 is formed on the insulation film 31, the sidewall conductive films 23, and the interlayer insulation film 11. A contact plug 25A embedded in the interlayer insulation film 24 and the insulation film 31 is formed on the upper electrode 17A and a contact plug 25B embedded in the interlayer insulation film 24 and the insulation film 31 is formed on the upper electrode 17B. A contact plug 27A embedded in the interlayer insulation film 11 is formed on the source/drain region 19B and a contact plug 27B embedded in the interlayer insulation film 11 is formed on the source/drain region 19C. Wiring layers 28A and 28B are formed on the contact plugs 27A and 27B, respectively. A contact plug 29A embedded in the interlayer insulation film 24 is formed on the wiring layer 28A and a contact plug 29B embedded in the interlayer insulation film 24 is formed on the wiring layer 28B. A wiring layer 30A is formed on the contact plugs 25A and 29A such that the contact plugs 25A and 29A are electrically connected to each other. A wiring layer 30B is formed on the contact plugs 25B and 29B such that the contact plugs 25B and 29B are electrically connected to each other. In the semiconductor device including the ferroelectric memory of the TC parallel-unit serial connection type, too, the same advantage as the first embodiment shown in FIG. 2 can be achieved from the ferroelectric capacitors.

### Second Embodiment

Next, a semiconductor device including a ferroelectric memory, according to the second embodiment of the present invention, will be explained.

FIG. 4 is a cross-sectional view showing the semiconductor device including the ferroelectric memory, according to the second embodiment. The conductive oxygen barrier film 13, the insulating buffer layer 14, the lower electrode 15, the ferroelectric film 16 and the upper electrode 17 are formed in order from a lower side, on the contact plug 12. A ferroelectric capacitor is composed of the lower electrode 15, the ferroelectric film 16 and the upper electrode 17. The insulation film 31 is formed on the upper electrode 17.

The side surfaces of the insulation film 31, the upper electrode 17, the ferroelectric film 16, the lower electrode 15, and the insulating buffer layer 14 are made to correspond to each other as shown in FIG. 4. Sidewall conductive films 32 are formed on the side surfaces of the lower electrode 15, the side surfaces of the buffer layer 14 and on the conductive oxygen barrier film 13. The side surfaces of the sidewall conductive films 32 and the conductive oxygen barrier film 13 are made to correspond to each other. The other constituent elements and advantage shown in FIG. 4 are the same as those of the first embodiment shown in FIG. 2.

Next, an example of applying the structure of the second embodiment shown in FIG. 4 to a TC-parallel unit serial-connection type ferroelectric memory will be explained.

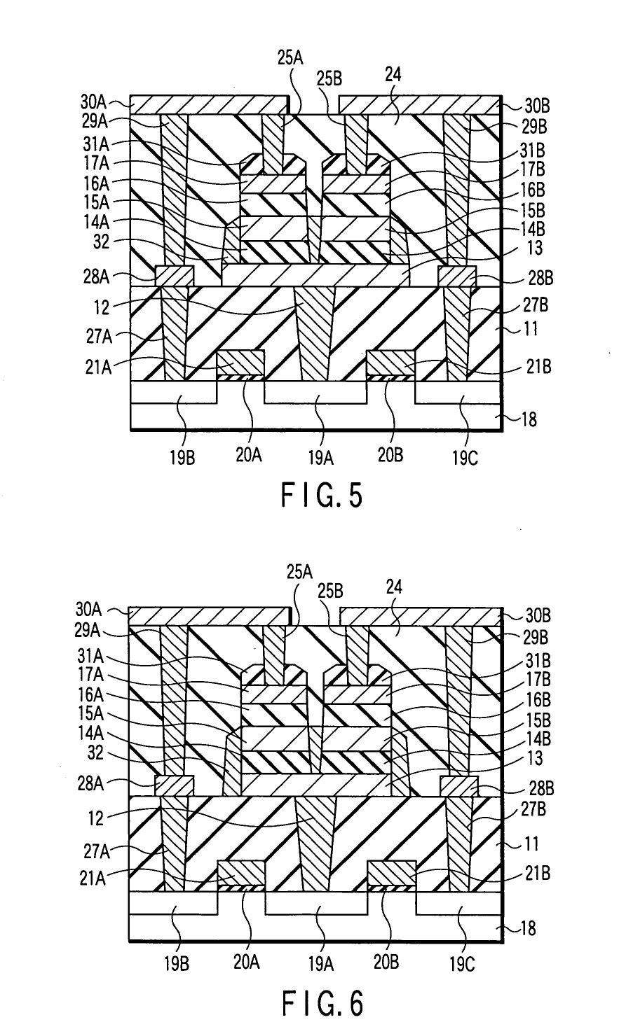

FIG. 5 is a cross-sectional view showing the TC-parallel unit serial-connection type ferroelectric memory, according to the second embodiment.

The conductive oxygen barrier film 13 is formed on the contact plug 12. As described above, the conductive oxygen barrier film 13 has conductivity and, particularly, has a function of preventing oxygen from reaching the contact plug 12 and the contact plug 12 from being oxidized during the heat treatment in the oxygen atmosphere.

Insulating buffer layers 14A and 14B are formed on the conductive oxygen barrier film 13 and are separated from each other. A lower electrode 15A, the ferroelectric film 16A, and the upper electrode 17A are formed in order from a lower side, on the buffer layer 14A. A lower electrode 15B, the ferroelectric film 16B, and the upper electrode 17B are formed in order from a lower side, on the buffer layer 14B. A first ferroelectric capacitor is composed of the lower electrode 15A, the ferroelectric film 16A, and the upper electrode 17A. A second ferroelectric capacitor is composed of the lower electrode 15B, the ferroelectric film 16B, and the upper electrode 17B. Insulation films 31A and 31B are formed on the upper electrodes 17A and 17B, respectively. As described above, the buffer layers 14A and 14B have a function of preventing the materials contained in the conductive oxygen barrier film 13 from diffusing to the lower electrodes 15A and 15B and further to the ferroelectric films 16A and 16B, and a function of preventing oxygen from reaching the contact plug 12 and the contact plug 12 from being oxidized during the heat treatment in an oxygen atmosphere.

The sidewall conductive films 32 are formed on the side surfaces of the lower electrodes 15A and 15B, the side surfaces of the buffer layers 14A and 14B, and on the conductive oxygen barrier film 13. The conductive oxygen barrier film 13 is electrically connected to the lower electrodes 15A and 15B by the sidewall conductive films 32. The contact plug 25A embedded in the interlayer insulation film 24 and the insulation film 31A is formed on the upper electrode 17A. The contact plug 25B embedded in the interlayer insulation film 24 and the insulation film 31B is formed on the upper electrode 17B. The other constituent elements and advantage shown in FIG. 5 are the same as those of the first embodiment shown in FIG. 3.

FIG. 6 is a cross-sectional view showing the TC-parallel unit serial-connection type ferroelectric memory, according to a modified example of the second embodiment.

The insulating buffer layers 14A and 14B are formed on the conductive oxygen barrier film 13. In FIG. 5, the side surfaces of the lower electrodes 15A and 15B and the side surfaces of the buffer layers 14A and 14B are made to correspond, and the sidewall conductive films 32 are formed on the side surfaces of the lower electrodes 15A and 15B, the side surfaces of the buffer layers 14A and 14B and on the conductive oxygen barrier film 13. In this modification, however, the side surfaces of the lower electrodes 15A and 15B, buffer layers 14A and 14B and conductive oxygen barrier film 13 are made to correspond, and the sidewall conductive films 32 are formed on the side surfaces of the lower electrodes 15A and 15B, the side surfaces of the buffer layers 14A and 14B and the side surfaces of the conductive oxygen barrier film 13. The other constituent elements and advantage shown in FIG. 6 are the same as those of the second embodiment shown in FIG. 5.

### Third Embodiment

Next, a semiconductor device including a ferroelectric memory, according to the third embodiment of the present invention, will be explained.

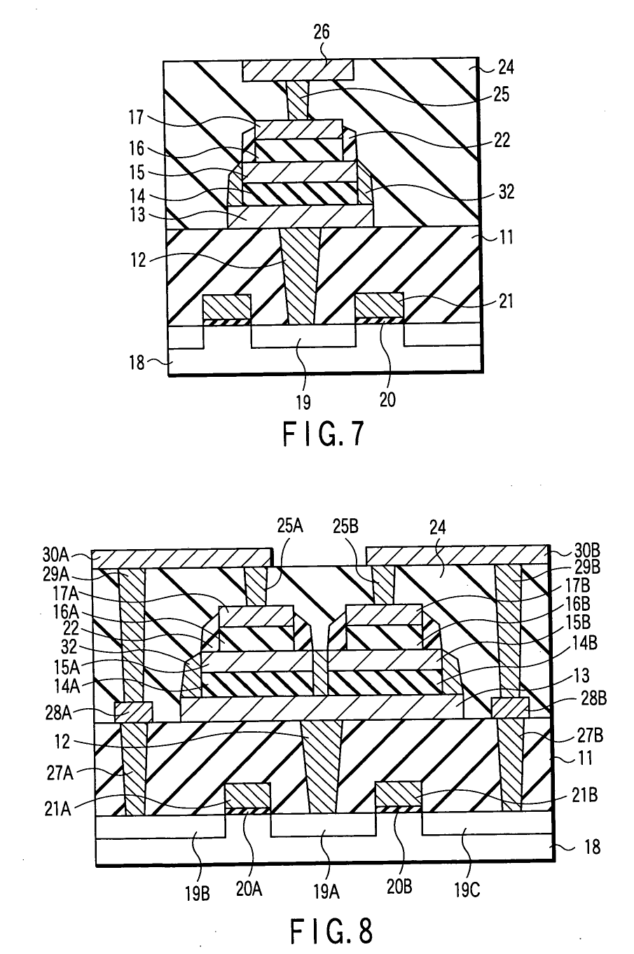

FIG. 7 is a cross-sectional view showing a semiconductor device including a ferroelectric memory, according to the third embodiment. In the first embodiment shown in FIG. 2, the side surfaces of the lower electrode 15, the buffer layer 14 and the conductive oxygen barrier film 13 are made to correspond and the sidewall conductive films 23 are formed on the side surfaces of the lower electrode 15, the buffer layer 14 and the conductive oxygen barrier film 13. In the third embodiment, however, the side surfaces of the lower electrode 15 and the buffer layer 14 are made to correspond and the sidewall conductive films 32 are formed on the side surfaces of the lower electrode 15, the side surfaces of the buffer layer 14, and on the conductive oxygen barrier film 13. The other constituent elements and advantage shown in FIG. 7 are the same as those of the first embodiment shown in FIG. 2.

Next, an example of applying the structure of the third embodiment shown in FIG. 7 to a TC-parallel unit serial-connection type ferroelectric memory will be explained.

FIG. 8 is a cross-sectional view showing the semiconductor device including the TC-parallel unit serial-connection type ferroelectric memory, according to the third embodiment.

The insulating buffer layers 14A and 14B are formed on the conductive oxygen barrier film 13 and are separated from each other. The lower electrode 15A, the ferroelectric film 16A, and the upper electrode 17A are formed in order from a lower side, on the buffer layer 14A. The lower electrode 15B, the ferroelectric film 16B, and the upper electrode 17B are formed in order from a lower side, on the buffer layer 14B. A first ferroelectric capacitor is composed of the lower electrode 15A, the ferroelectric film 16A, and the upper electrode 17A. A second ferroelectric capacitor is composed of the lower electrode 15B, the ferroelectric film 16B, and the upper electrode 17B.

The sidewall insulation films 22 are formed on the side surfaces of the ferroelectric film 16A, the side surfaces of the upper electrode 17A and on the lower electrode 15A, and also formed on the side surfaces of the ferroelectric film 16B, the side surfaces of the upper electrode 17B and on the lower electrode 15B. Moreover, the sidewall conductive films 32 are formed on the side surfaces of the lower electrodes 15A and 15B, the side surfaces of the buffer layers 14A and 14B, and on the conductive oxygen barrier film 13. The conductive oxygen barrier film 13 is electrically connected to the lower electrodes 15A and 15B by the sidewall conductive films 32. Furthermore, the contact plug 25A embedded in the interlayer insulation film 24 is formed on the upper electrode 17A and the contact plug 25B embedded in the interlayer insulation film 24 is formed on the upper electrode 17B. The other constituent elements and advantage shown in FIG. 8 are the same as those of the first embodiment shown in FIG. 3.

### Fourth Embodiment

Next, a semiconductor device including a ferroelectric memory, according to the fourth embodiment of the present invention, will be explained.

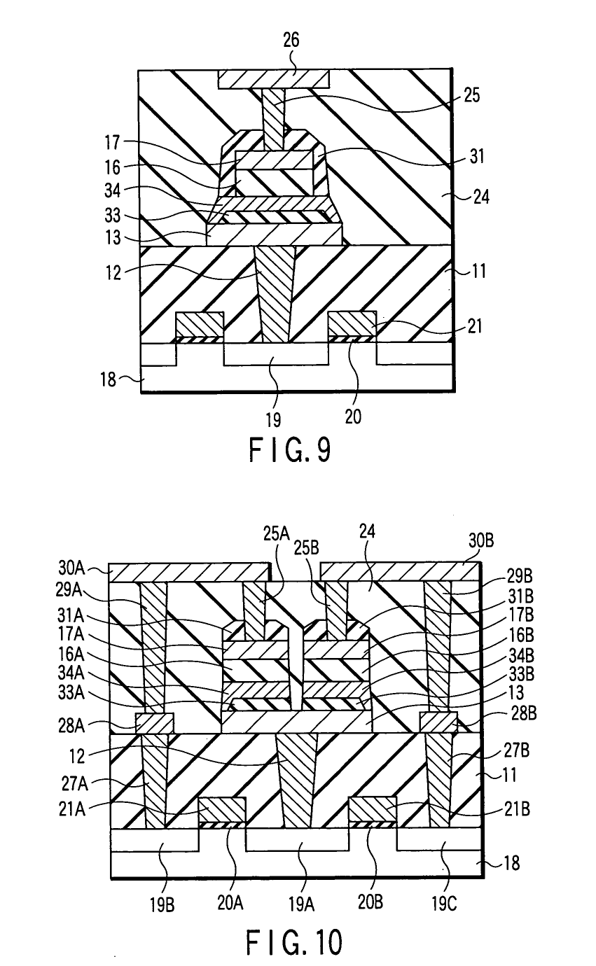

FIG. 9 is a cross-sectional view showing the semiconductor device including the ferroelectric memory, according to the fourth embodiment. The conductive oxygen barrier film 13 is formed on the contact plug 12. An insulating buffer layer 33 is formed on a central portion of the top surface of the conductive oxygen barrier film 13. A lower electrode 34 is formed on a peripheral portion of the top surface of the conductive oxygen barrier film 13 and on the buffer layer 33. The ferroelectric film 16 and the upper electrode 17 are formed in order from a lower side, on the lower electrode 34. A ferroelectric capacitor is composed of the lower electrode 34, the ferroelectric film 16, and the upper electrode 17. The buffer layer 33 has a function of preventing the materials contained in the conductive oxygen barrier film 13 from diffusing to the lower electrode 34 and further to the ferroelectric film 16, and a function of preventing oxygen from reaching the contact plug 12 and the contact plug 12 from being oxidized during the heat treatment in an oxygen atmosphere.

The insulation film 31 is formed on the top surface and side surfaces of the upper electrode 17, the side surfaces of the ferroelectric film 16, and on the lower electrode 34. The contact plug 25 embedded in the interlayer insulation film 24 and the insulation film 31 is formed on the upper electrode 17. The other constituent elements and advantage shown in FIG. 9 are the same as those of the first embodiment shown in FIG. 2.

Next, an example of applying the structure of the fourth embodiment shown in FIG. 9 to a TC-parallel unit serial-connection type ferroelectric memory will be explained.

FIG. 10 is a cross-sectional view showing the semiconductor device including the TC-parallel unit serial-connection type ferroelectric memory, according to the fourth embodiment.

The conductive oxygen barrier film 13 is formed on the contact plug 12. Insulating buffer layers 33A and 33B are formed at the central portion of the top surface of the conductive oxygen barrier film 13. A lower electrode 34A is formed on the buffer layer 33A and on the peripheral portion of the top surface of the conductive oxygen barrier film 13. A lower electrode 34B is formed on the buffer layer 33B and on the other peripheral portion of the top surface of the conductive oxygen barrier film 13. The ferroelectric film 16A and the upper electrode 17A are formed in order from a lower side, on the lower electrode 34A. The ferroelectric film 16B and the upper electrode 17B are formed in order from a lower side, on the lower electrode 34B. A first ferroelectric capacitor is composed of the lower electrode 34A, the ferroelectric film 16A, and the upper electrode 17A. A second ferroelectric capacitor is composed of the lower electrode 34B, the ferroelectric film 16B, and the upper electrode 17B. The insulation films 31A and 31B are formed on the upper electrodes 17A and 17B, respectively. The contact plug 25A embedded in the interlayer insulation film 24 and the insulation film 31A is formed on the upper electrode 17A. The contact plug 25B embedded in the interlayer insulation film 24 and the insulation film 31B is formed on the upper electrode 17B. The other constituent elements and advantage shown in FIG. 10 are the same as those of the first embodiment shown in FIG. 3.

### Fifth Embodiment

Next, a semiconductor device including a ferroelectric memory, according to the fifth embodiment of the present invention, will be explained.

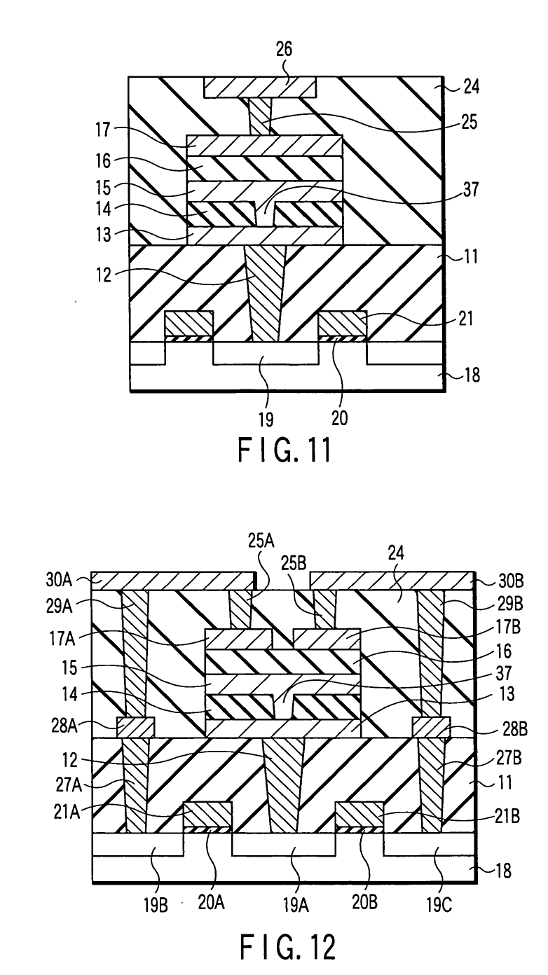

FIG. 11 is a cross-sectional view showing a semiconductor device including a ferroelectric memory, according to the fifth embodiment. The conductive oxygen barrier film 13 is formed on the contact plug 12. The insulating buffer layer 14 is formed on the conductive oxygen barrier film 13. A hole is formed in the buffer layer 14 such that the surface of the conductive oxygen barrier film 13 is exposed through the hole. The lower electrode 15 is formed on the buffer layer 14. The hole of the buffer layer 14 is filled with the material of the lower electrode 15 and a contact plug 37 is thereby formed. The conductive oxygen barrier film 13 and the lower electrode 15 are electrically connected to each other by the contact plug 37.

The ferroelectric film 16 and the upper electrode 17 are formed in order from a lower side, on the lower electrode 15. A ferroelectric capacitor is composed of the lower electrode 15, the ferroelectric film 16, and the upper electrode 17. The other constituent elements and advantage shown in FIG. 11 are the same as those of the first embodiment shown in FIG. 2.

Next, an example of applying the structure of the fifth embodiment shown in FIG. 11 to a TC-parallel unit serial-connection type ferroelectric memory will be explained.

FIG. 12 is a cross-sectional view showing the TC-parallel unit serial-connection type ferroelectric memory, according to the fifth embodiment.

The conductive oxygen barrier film 13 is formed on the contact plug 12. The insulating buffer layer 14 is formed on the conductive oxygen barrier film 13. A hole is formed in the buffer layer 14 such that the surface of the conductive oxygen barrier film 13 is exposed through the hole. The lower electrode 15 is formed on the buffer layer 14. The hole of the buffer layer 14 is filled with the material of the lower electrode 15 and the contact plug 37 is thereby formed. The conductive oxygen barrier film 13 and the lower electrode 15 are electrically connected to each other by the contact plug 37.

The ferroelectric film 16 is formed on the lower electrode 15. The upper electrodes 17A and 17B are formed on the ferroelectric film 16 and separated from each other. A first ferroelectric capacitor is composed of the lower electrode 15, the ferroelectric film 16, and the upper electrode 17A. A second ferroelectric capacitor is composed of the lower electrode 15, the ferroelectric film 16, and the upper electrode 17B. The contact plug 25A embedded in the interlayer insulation film 24 is formed on the upper electrode 17A. The contact plug 25B embedded in the interlayer insulation film 24 is formed on the upper electrode 17B. The other constituent elements and advantage shown in FIG. 12 are the same as those of the first embodiment shown in FIG. 3.

Next, a multilayer film used in a ferroelectric memory according to the sixth to tenth embodiments of the present invention will be explained.

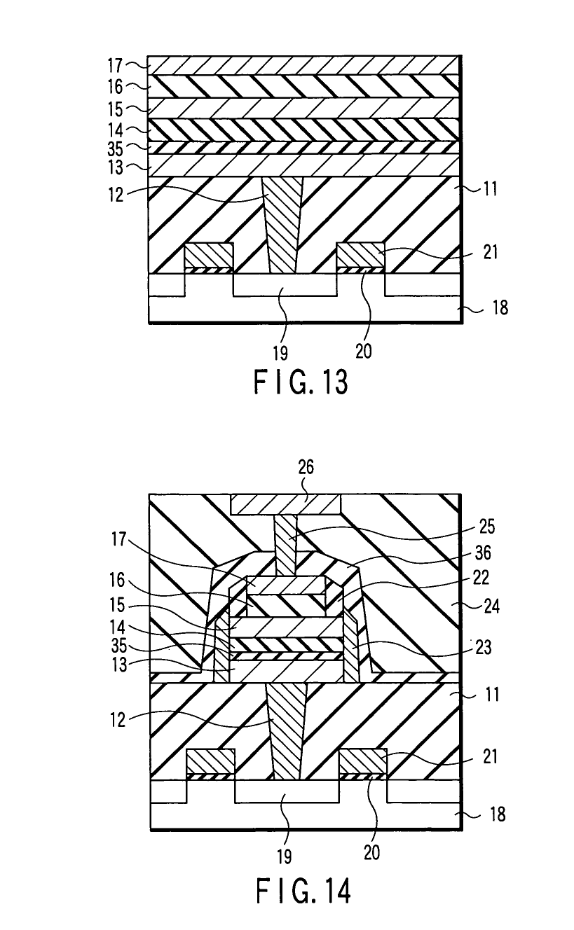

FIG. 13 is a cross-sectional view showing the multilayer film used in a semiconductor device according to sixth to tenth embodiments of the present invention.

The conductive oxygen barrier film 13 is formed on the contact plug 12 embedded in the interlayer insulation film 11 as shown in FIG. 13. An insulating oxygen barrier film 35 is formed on the conductive oxygen barrier film 13. The insulating buffer layer 14 is formed on the insulating oxygen barrier film 35. In other words, the insulating oxygen barrier film 35 is added between the conductive oxygen barrier film 13 and the buffer layer 14 in the structure shown in FIG. 1. The conductive oxygen barrier film 13 has conductivity and shuts out penetration of oxygen. In other words, the conductive oxygen barrier film 13 has a function of preventing oxygen from reaching the contact plug 12. The conductive oxygen barrier film 13 is formed of materials including iridium (Ir), iridium oxide (IrO₂), ruthenium (Ru), ruthenium oxide (RuO₂) or the like. The insulating oxygen barrier film 35 has insulation characteristics and shuts out penetration of oxygen. In other words, the conductive oxygen barrier film 13 has a function of preventing oxygen from reaching the contact plug 12. In other words, the insulating oxygen barrier film 35 is formed of materials including Alumina (Al₂O₃), a silicon nitride film (SiN), SiON, titanium oxide (TiO₂), PZT or the like.

The buffer layer 14 has a function of preventing the materials contained in the conductive oxygen barrier film 13 or the insulating oxygen barrier film 35 from diffusing to the lower electrode 15 and the ferroelectric film 16, and a function of preventing oxygen from reaching the contact plug 12. The buffer layer 14 also has a function of preventing oxygen from reaching the contact plug 12. The buffer layer 14 is composed of a silicon oxide film (SiO₂) such as TEOS or a silicon nitride film (SiN), or formed of materials including SiON, alumina (Al₂O₃), PZT, titanium oxide (TiO₂), STO or the like.

In the above-described embodiments, the characteristic of shutting out penetration of oxygen, in the conductive oxygen barrier film 13 and the insulating oxygen barrier film 35 has been explained. However, if the insulating oxygen barrier film 35 has the characteristic of shutting out penetration of oxygen, the conductive oxygen barrier film 13 does not need to have this characteristic. Thus, the conductive oxygen barrier film 13 may be formed of the materials including platinum (Pt).

### Sixth Embodiment

FIG. 14 is a cross-sectional view showing a semiconductor device including a ferroelectric memory, according to the sixth embodiment of the present invention.

The contact plug 12 embedded in the interlayer insulation film 11 is formed on the source/drain regions 19. The conductive oxygen barrier film 13 is formed on the contact plug 12 and electrically connected to the contact plug 12. As described above, the conductive oxygen barrier film 13 has conductivity and has a function of preventing penetration of oxygen, especially preventing oxygen from reaching the contact plug 12 and the contact plug 12 from being oxidized during the heat treatment in an oxygen atmosphere. The conductive oxygen barrier film 13 is formed of materials including, for example, Ir, IrO₂, Ru, RuO₂ or the like as described above.

The insulating oxygen barrier film 35 is formed on the conductive oxygen barrier film 13. As described above, the insulating oxygen barrier film 35 has insulation characteristics and has a function of preventing penetration of oxygen, especially preventing oxygen from reaching the contact plug 12 and the contact plug 12 from being oxidized during the heat treatment in an oxygen atmosphere. The insulating buffer layer 14 is formed on the insulating oxygen barrier film 35. The lower electrode 15 is formed on the buffer layer 14. The ferroelectric film 16 is formed on the lower electrode 15. The upper electrode 17 is formed on the ferroelectric film 16. A ferroelectric capacitor is composed of the lower electrode 15, the ferroelectric film 16 and the upper electrode 17.

As described above, the buffer layer 14 has a function of preventing the materials contained in the conductive oxygen barrier film 13 or the insulating oxygen barrier film 35 from diffusing to the lower electrode 15 and further to the ferroelectric film 16, and a function of preventing oxygen from reaching the contact plug 12 and the contact plug 12 from being oxidized during the heat treatment in an oxygen atmosphere. The buffer layer 14 is formed of materials containing SiO₂ such as TEOS or the like, SiN, SiON, Al₂O₃, PZT, TiO₂, STO or the like.

The sidewall insulation films 22 are formed on the side surfaces of the ferroelectric film 16, the side surfaces of the upper electrode 17, and the top surface of the lower electrode 15. The sidewall insulation films 22 are composed of a silicon oxide film such as TEOS, or formed of materials containing Al₂O₃ or the like.

Furthermore, the sidewall conductive films 23 are formed on the side surfaces of the conductive oxygen barrier film 13, the side surfaces of the buffer layer 14, and the side surfaces of the lower electrode 15. The sidewall conductive films 23 are formed of materials containing platinum (Pt) or the like. The conductive oxygen barrier film 13 and the lower electrode 15 are electrically connected to each other by the sidewall conductive films 23. The sidewall insulation films 22 have a function of preventing the lower electrode 15 and the upper electrode 17 from being electrically connected by the sidewall conductive films 23.

As shown in FIG. 14, an insulating oxygen barrier film 36 is formed on the upper electrode 17, the sidewall insulation films 22, the sidewall conductive films 23 and the interlayer insulation film 11. In other words, the insulating oxygen barrier film 36 is formed to cover the ferroelectric capacitor arranged on the interlayer insulation film 11. The insulating oxygen barrier film 36 has a function of shutting out penetration of the atoms of hydrogen or the like which deteriorate the ferroelectric capacitor into the ferroelectric capacitor, and a function of preventing oxygen from reaching the contact plug 12 and the contact plug 12 from being oxidized during the heat treatment in an oxygen atmosphere.

The interlayer insulation film 24 is formed on the insulating oxygen barrier film 36. The contact plug 25 embedded in the interlayer insulation film 24 and the insulating oxygen barrier film 36 is formed on the upper electrode 17. The wiring layer 26 is formed on the contact plug 25. The other constituent elements and advantage shown in FIG. 14 are the same as those of the first embodiment shown in FIG. 1.

In the semiconductor device thus formed, diffusion of the chemical elements contained in the conductive oxygen barrier film 13 into the lower electrode 15 or the ferroelectric film 16 can be prevented by arranging the insulating oxygen barrier film 35 and the buffer layer 14 between the conductive oxygen barrier film 13 and the lower electrode 15, and deterioration of the lower electrode 15 and the ferroelectric film 16 can be thereby prevented. In addition, the difference between the stresses generated on the conductive oxygen barrier film 13 and the lower electrode 15 can be reduced during the heat treatment, and defectiveness such as degradation of close contact between the conductive oxygen barrier film 13 and the lower electrode 15 can be prevented.

During the heat treatment in the oxygen atmosphere, penetrating oxygen does not reach the contact plug 12 as it is shut out further certainly by the insulating oxygen barrier film 35 and the conductive oxygen barrier film 13. In addition, as the insulating oxygen barrier film 36 is arranged to cover the ferroelectric capacitor, penetration of oxygen into the ferroelectric capacitor and the contact plug 12 can be further prevented. For this reason, oxidization of the contact plug 12 during the heat treatment can be further prevented.

Moreover, oxidation of the contact plug can be prevented further certainly as the materials of the conductive oxygen barrier film 13 and the insulating oxygen barrier film 35 can be optimized without considering diffusion into the lower electrode 15 or the ferroelectric film 16 by arranging the buffer layer 14.

For these reasons, deterioration of characteristics and reduction of reliability in the ferroelectric capacitor can be restricted. As a result, writing and reading of “1” and “0” can be performed easily with high reliability in the memory including the ferroelectric capacitor as the amount of charge (polarization) stored in the ferroelectric capacitor can be maintained without reduction.

Next, an example of applying the structure of the sixth embodiment shown in FIG. 14 to a TC-parallel unit serial-connection type ferroelectric memory will be explained.

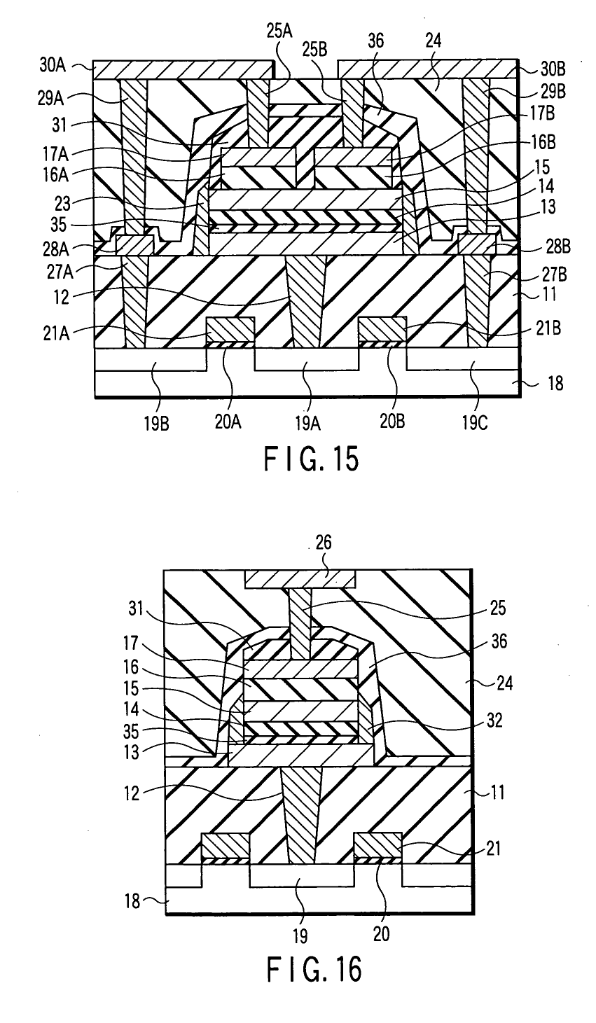

FIG. 15 is a cross-sectional view showing the TC-parallel unit serial-connection type ferroelectric memory, according to the second embodiment.

The conductive oxygen barrier film 13 is formed on the contact plug 12. As described above, the conductive oxygen barrier film 13 has conductivity, and has a function of preventing oxygen from reaching the contact plug 12 and the contact plug 12 from being oxidized during the heat treatment in the oxygen atmosphere.

The insulating oxygen barrier film 35 is formed on the conductive oxygen barrier film 13. The insulating buffer layer 14 is formed on the insulating oxygen barrier film 35. The lower electrode 15 is formed on the buffer layer 14. The ferroelectric films 16A and 16B are formed on the lower electrode 15 and separated from each other. The upper electrode 17A is formed on the ferroelectric film 16A. The upper electrode 17B is formed on the ferroelectric film 16B. A first ferroelectric capacitor is composed of the lower electrode 15, the ferroelectric film 16A and the upper electrode 17A. A second ferroelectric capacitor is composed of the lower electrode 15, the ferroelectric film 16B and the upper electrode 17B.

The insulation film 31 is formed on the side surfaces of the ferroelectric films 16A and 16B, the top surfaces and side surfaces of the upper electrodes 17A and 17B, and the top surface of the lower electrode 15. Moreover, the sidewall conductive films 23 are formed on the side surfaces of the conductive oxygen barrier film 13, the side surfaces of the insulating oxygen barrier film 35, the side surfaces of the buffer layer 14, and the side surfaces of the lower electrode 15. The conductive oxygen barrier film 13 and the lower electrode 15 are electrically connected to each other by the sidewall conductive films 23. The insulation film 31 has a function of preventing the lower electrode 15 and the upper electrodes 17A and 17B from being electrically connected by the sidewall conductive films 23.

As shown in FIG. 15, the insulating oxygen barrier film 36 is formed on the insulation film 31, the sidewall conductive films 23, and the interlayer insulation film 11. In other words, the insulating oxygen barrier film 36 is formed to cover the first and second ferroelectric capacitors arranged on the interlayer insulation film 11. As described above, the insulating oxygen barrier film 36 has a function of shutting out penetration of atoms of oxygen or the like which deteriorate the ferroelectric capacitors, into the ferroelectric capacitors, and a function of preventing oxygen from reaching the contact plug 12 and the contact plug 12 from being oxidized during the heat treatment in an oxygen atmosphere.

The contact plug 25A embedded in the interlayer insulation film 24, the insulating oxygen barrier film 36 and the insulation film 31 is formed on the upper electrode 17A. The contact plug 25B embedded in the interlayer insulation film 24, the insulating oxygen barrier film 36 and the insulation film 31 is formed on the upper electrode 17B. The other constituent elements and advantage shown in FIG. 15 are the same as those of the first embodiment shown in FIG. 3.

In the above-described embodiments, the characteristic of shutting out penetration of oxygen, in the conductive oxygen barrier film 13, the insulating oxygen barrier film 35 and the insulating oxygen barrier film 36 has been explained. However, if the insulating oxygen barrier film 35 and the insulating oxygen barrier film 36 have the characteristic of shutting out penetration of oxygen, the conductive oxygen barrier film 13 does not need to have this characteristic. Thus, the conductive oxygen barrier film 13 may be formed of the materials including platinum (Pt).

### Seventh Embodiment

Next, a semiconductor device including a ferroelectric memory, according to the seventh embodiment of the present invention, will be explained.

FIG. 16 is a cross-sectional view showing the semiconductor device including the ferroelectric memory, according to the seventh embodiment. The conductive oxygen barrier film 13, the insulating oxygen barrier film 35, the insulating buffer layer 14, the lower electrode 15, the ferroelectric film 16 and the upper electrode 17 are formed in order from a lower side, on the contact plug 12. A ferroelectric capacitor is composed of the lower electrode 15, the ferroelectric film 16 and the upper electrode 17. The insulation film 31 is formed on the upper electrode 17.

The side surfaces of the insulation film 31, the upper electrode 17, the ferroelectric film 16, the lower electrode 15, and the insulating buffer layer 14 and the insulating oxygen barrier film 35 are made to correspond to each other as shown in FIG. 16. The sidewall conductive films 32 are formed on the side surfaces of the lower electrode 15, the side surfaces of the buffer layer 14, the side surfaces of the insulating oxygen barrier film 35, and the top surface of the conductive oxygen barrier film 13. The side surfaces of the sidewall conductive films 32 and the conductive oxygen barrier film 13 are made to correspond to each other.

The insulating oxygen barrier film 36 is formed on the top surface of the insulation film 31, the side surfaces of the upper electrode 17, the side surfaces of ferroelectric film 16, the top surfaces of the sidewall conductive films 32, the side surfaces of conductive oxygen barrier film 13, and the top surface of the interlayer insulation film 11. In other words, the insulating oxygen barrier film 36 is formed to cover the ferroelectric capacitor arranged on the interlayer insulation film 11.

The interlayer insulation film 24 is formed on the insulating oxygen barrier film 36. The contact plug 25 embedded in the interlayer insulation film 24, the insulating oxygen barrier film 36 and the insulation film 31 is formed on the upper electrode 17. The wiring layer 26 is formed on the contact plug 25. The other constituent elements and advantage shown in FIG. 16 are the same as those of the sixth embodiment shown in FIG. 14.

Next, an example of applying the structure of the seventh embodiment shown in FIG. 16 to a TC-parallel unit serial-connection type ferroelectric memory will be explained.

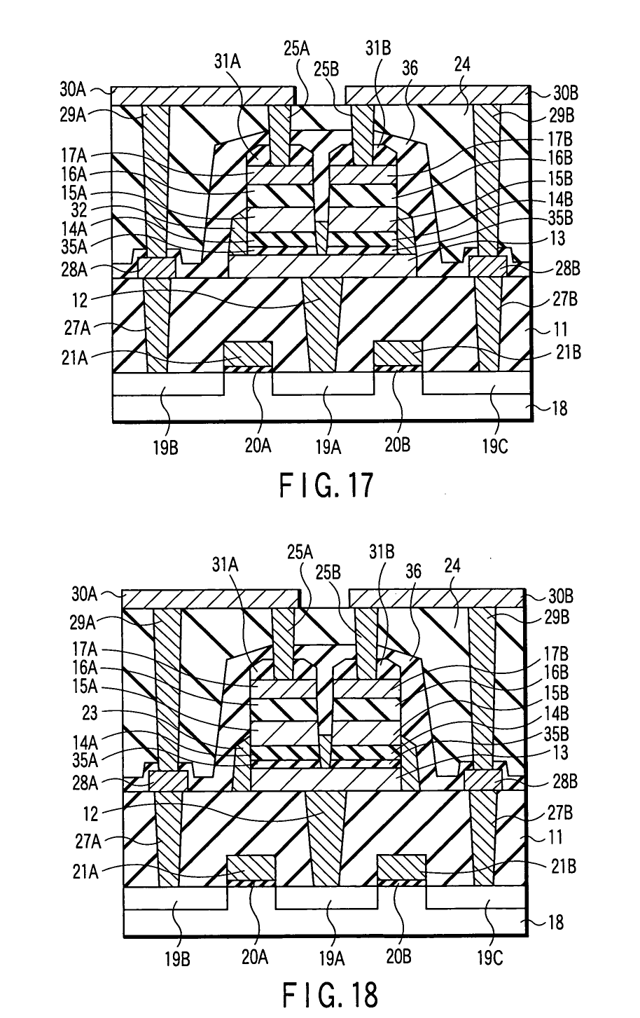

FIG. 17 is a cross-sectional view showing the TC-parallel unit serial-connection type ferroelectric memory, according to the seventh embodiment.

The conductive oxygen barrier film 13 is formed on the contact plug 12. Insulating oxygen barrier films 35A and 35B are formed on the conductive oxygen barrier film 13 and separated from each other. The buffer layer 14A, the lower electrode 15A, the ferroelectric film 16A, and the upper electrode 17A are formed in order from a lower side, on the insulating oxygen barrier film 35A. Similarly, the buffer layer 14B, the lower electrode 15B, the ferroelectric film 16B, and the upper electrode 17B are formed in order from a lower side, on the insulating oxygen barrier film 35B. A first ferroelectric capacitor is composed of the lower electrode 15A, the ferroelectric film 16A, and the upper electrode 17A. A second ferroelectric capacitor is composed of the lower electrode 15B, the ferroelectric film 16B, and the upper electrode 17B.

The insulation films 31A and 31B are formed on the upper electrodes 17A and 17B, respectively. The sidewall conductive films 32 are formed on the side surfaces of the lower electrodes 15A and 15B, the side surfaces of the buffer layers 14A and 14B, the side surfaces of the insulating oxygen barrier films 35A and 35B, and the top surface of the conductive oxygen barrier film 13. The conductive oxygen barrier film 13 is electrically connected to the lower electrodes 15A and 15B by the sidewall conductive films 32.

The insulating oxygen barrier film 36 is formed on the top surfaces of the insulation films 31A and 31B, the side surfaces of the upper electrodes 17A and 17B, the side surfaces of the ferroelectric films 16A and 16B, the top surface of the sidewall conductive films 32, the side surfaces of the conductive oxygen barrier film 13, and the top surface of the interlayer insulation film 11. In other words, the insulating oxygen barrier film 36 is formed to cover the first and second ferroelectric capacitors arranged on the interlayer insulation film 11.

Furthermore, the contact plug 25A embedded in the interlayer insulation film 24, the insulating oxygen barrier film 36 and the insulation film 31A is formed on the upper electrode 17A. The contact plug 25B embedded in the interlayer insulation film 24, the insulating oxygen barrier film 36 and the insulation film 31B is formed on the upper electrode 17B. The other constituent elements and advantage shown in FIG. 17 are the same as those of the sixth embodiment shown in FIG. 15.

FIG. 18 is a cross-sectional view showing the TC-parallel unit serial-connection type ferroelectric memory, according to a modified example of the seventh embodiment.

In FIG. 17, the side surfaces of the lower electrodes 15A and 15B, the buffer layers 14A and 14B, and the insulating oxygen barrier films 35A and 35B are made to correspond to each other, and the sidewall conductive films 32 are formed on these side surfaces. In the modified example, however, the side surfaces of the lower electrodes 15A and 15B, the buffer layers 14A and 14B, the insulating oxygen barrier films 35A and 35B, and the conductive oxygen barrier film 13 are made to correspond to each other, and the sidewall conductive films 23 are formed on these side surfaces. The other constituent elements and advantage shown in FIG. 18 are the same as those of the embodiment shown in FIG. 17.

In the above-described embodiments, the characteristic of shutting out penetration of oxygen, in the conductive oxygen barrier film 13, the insulating oxygen barrier film 35 (35A and 35B) and the insulating oxygen barrier film 36 has been explained. However, if the insulating oxygen barrier films 35 (35A and 35B) and 36 have the characteristic of shutting out penetration of oxygen, the conductive oxygen barrier film 13 does not need to have this characteristic. Thus, the conductive oxygen barrier film 13 may be formed of the materials including platinum (Pt).

### Eighth Embodiment

Next, a semiconductor device including a ferroelectric memory, according to the eighth embodiment of the present invention, will be explained.

FIG. 19 is a cross-sectional view showing a semiconductor device including a ferroelectric memory, according to the eighth embodiment. In the embodiment shown in FIG. 14, the side surfaces of the lower electrode 15, the buffer layer 14, the insulating oxygen barrier film 35 and the conductive oxygen barrier film 13 are made to correspond and the sidewall conductive films 23 are formed on these side surfaces. In the eighth embodiment, however, the side surfaces of the lower electrode 15, the buffer layer 14 and the insulating oxygen barrier film 35 other than the conductive oxygen barrier film 13 are made to correspond and the sidewall conductive films 32 are formed on these side surfaces. The other constituent elements and advantage shown in FIG. 19 are the same as those of the first embodiment shown in FIG. 14.

Next, an example of applying the structure of the eighth embodiment shown in FIG. 19 to a TC-parallel unit serial-connection type ferroelectric memory will be explained.

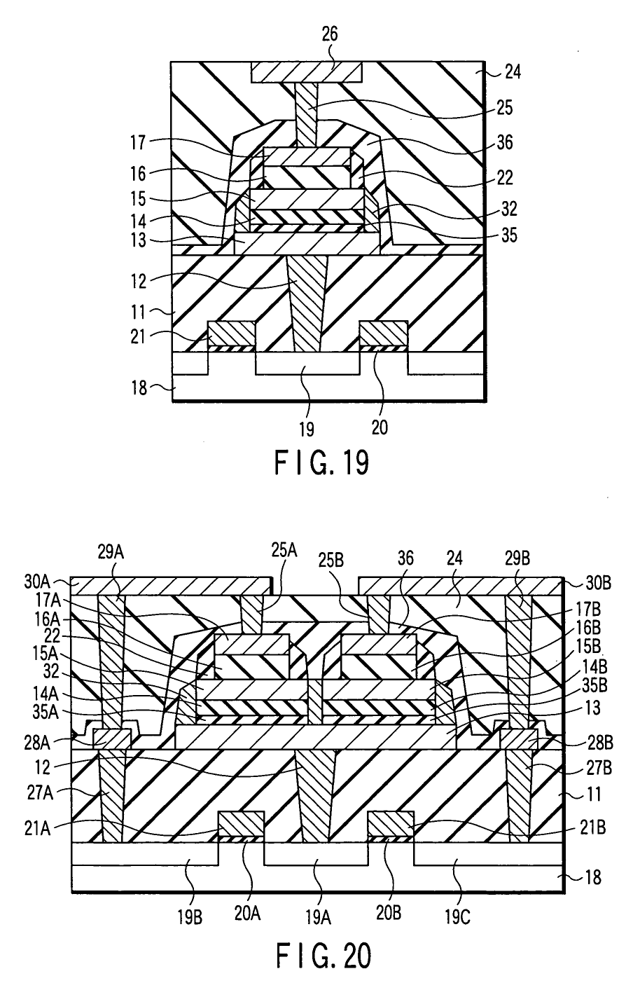

FIG. 20 is a cross-sectional view showing the TC-parallel unit serial-connection type ferroelectric memory, according to the eighth embodiment.

The conductive oxygen barrier film 13 is formed on the contact plug 12. The insulating oxygen barrier films 35A and 35B are formed on the conductive oxygen barrier film 13 and separated from each other. The insulating buffer layer 14A, the lower electrode 15A, the ferroelectric film 16A, and the upper electrode 17A are formed in order from a lower side, on the insulating oxygen barrier film 35A. Similarly, the insulating buffer layer 14B, the lower electrode 15B, the ferroelectric film 16B, and the upper electrode 17B are formed in order from a lower side, on the insulating oxygen barrier film 35B. A first ferroelectric capacitor is composed of the lower electrode 15A, the ferroelectric film 16A, and the upper electrode 17A. A second ferroelectric capacitor is composed of the lower electrode 15B, the ferroelectric film 16B, and the upper electrode 17B.

The sidewall insulation film 22 is formed on the side surfaces of the upper electrode 17A, the side surfaces of the ferroelectric film 16A and the top surface of the lower electrode 15A. The sidewall insulation film 22 is also formed on the side surfaces of the upper electrode 17B, the side surfaces of the ferroelectric film 16B and the top surface of the lower electrode 15B. Moreover, the sidewall conductive films 32 are formed on the side surfaces of the lower electrodes 15A and 15B, the side surfaces of the buffer layers 14A and 14B, the side surfaces of the insulating oxygen barrier films 35A and 35B, and the top surface of the conductive oxygen barrier film 13. The conductive oxygen barrier film 13 is electrically connected to the lower electrodes 15A and 15B by the sidewall conductive films 32. The sidewall insulation films 22 have a function of preventing the sidewall conductive film 32 from making electric connection between the lower electrode 15A and the upper electrode 17A or between the lower electrode 15B and the upper electrode 17B.

The insulating oxygen barrier film 36 is formed on the upper electrodes 17A and 17B, the sidewall insulation films 22, the sidewall conductive films 32, the side surfaces of the conductive oxygen barrier film 13, and the interlayer insulation film 11 as shown in FIG. 20. In other words, the insulating oxygen barrier film 36 is formed to cover the first and second ferroelectric capacitors arranged on the interlayer insulation film 11.

The contact plug 25A embedded in the interlayer insulation film 24 and the insulating oxygen barrier film 36 is formed on the upper electrode 17A. The contact plug 25B embedded in the interlayer insulation film 24 and the insulating oxygen barrier film 36 is formed on the upper electrode 17B. The other constituent elements and advantage shown in FIG. 20 are the same as those of the sixth embodiment shown in FIG. 15.

In the above-described embodiments, the characteristic of shutting out penetration of oxygen, in the conductive oxygen barrier film 13, the insulating oxygen barrier film 35 (35A and 35B) and the insulating oxygen barrier film 36 has been explained. However, if the insulating oxygen barrier films 35 (35A and 35B) and 36 have the characteristic of shutting out penetration of oxygen, the conductive oxygen barrier film 13 does not need to have this characteristic. Thus, the conductive oxygen barrier film 13 may be formed of the materials including platinum (Pt).

### Ninth Embodiment

Next, a semiconductor device including a ferroelectric memory, according to the ninth embodiment of the present invention, will be explained.

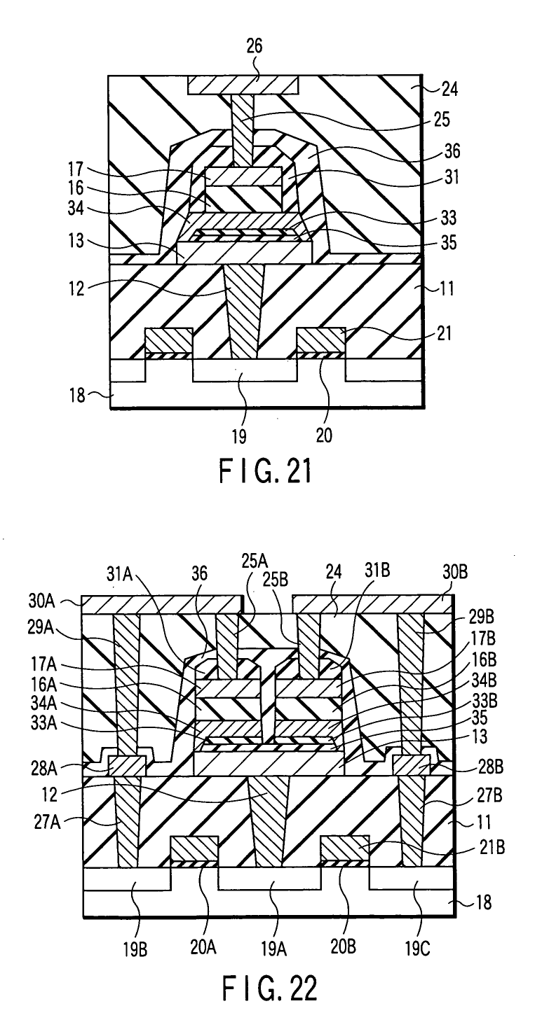

FIG. 21 is a cross-sectional view showing the semiconductor device including the ferroelectric memory, according to the fourth embodiment. In the ninth embodiment of FIG. 21, the insulating oxygen barrier films 35 and 36 are added to the fourth embodiment of FIG. 9.

The insulating oxygen barrier film 35 is formed between the conductive oxygen barrier film 13 and the buffer layer 33 as shown in FIG. 21. The insulating oxygen barrier film 36 is formed on the insulation film 31, the side surfaces of the lower electrode 34, the side surfaces of the conductive oxygen barrier film 13, and the interlayer insulation film 11. In other words, the insulating oxygen barrier film 36 is formed to cover the ferroelectric capacitor arranged on the interlayer insulation film 11. The other constituent elements and advantage shown in FIG. 21 are the same as those of the fourth embodiment shown in FIG. 9.

Next, an example of applying the structure of the ninth embodiment shown in FIG. 21 to a TC-parallel unit serial-connection type ferroelectric memory will be explained.

FIG. 22 is a cross-sectional view showing the TC-parallel unit serial-connection type ferroelectric memory, according to the ninth embodiment. In the ninth embodiment of FIG. 22, the insulating oxygen barrier films 35 and 36 are added to the fourth embodiment of FIG. 10.

The insulating oxygen barrier film 35 is formed between the conductive oxygen barrier film 13 and the buffer layers 33A, 33B as shown in FIG. 22. The insulating oxygen barrier film 36 is formed on the insulation films 31A and 31B, the side surfaces of the upper electrodes 17A and 17B, the side surfaces of the ferroelectric films 16A and 16B, the side surfaces of the lower electrode 34, the side surfaces of the conductive oxygen barrier film 13, and the interlayer insulation film 11. In other words, the insulating oxygen barrier film 36 is formed to cover the first and second ferroelectric capacitors arranged on the interlayer insulation film 11. The other constituent elements and advantage shown in FIG. 22 are the same as those of the fourth embodiment shown in FIG. 10.

In the above-described embodiments, the characteristic of shutting out penetration of oxygen, in the conductive oxygen barrier film 13, the insulating oxygen barrier films 35 and 36 has been explained. However, if the insulating oxygen barrier films 35 and 36 have the characteristic of shutting out penetration of oxygen, the conductive oxygen barrier film 13 does not need to have this characteristic. Thus, the conductive oxygen barrier film 13 may be formed of the materials including platinum (Pt).

### Tenth Embodiment

Next, a semiconductor device including a ferroelectric memory, according to the tenth embodiment of the present invention, will be explained.

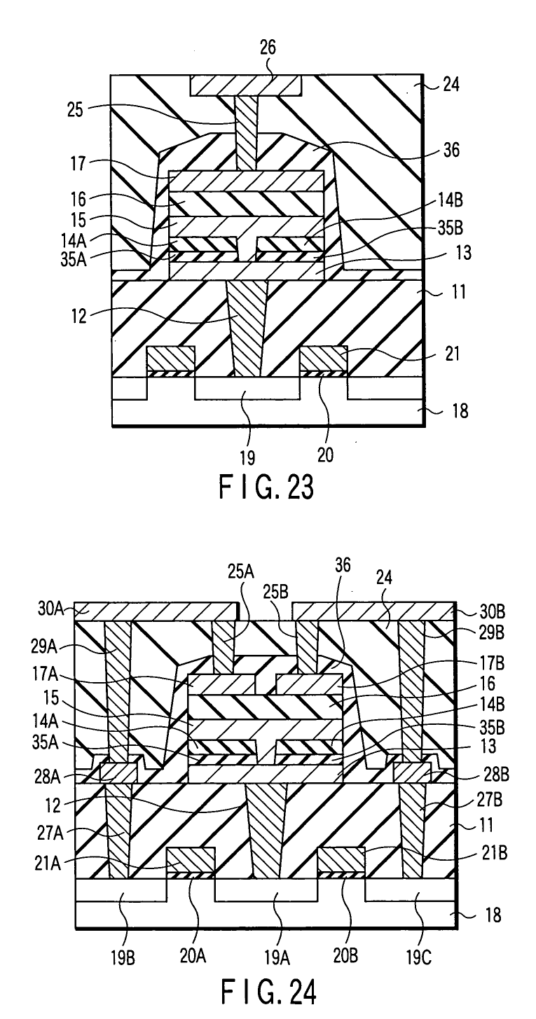

FIG. 23 is a cross-sectional view showing a semiconductor device including the ferroelectric memory, according to the tenth embodiment. In the tenth embodiment of FIG. 23, the insulating oxygen barrier films 35A, 35B and 36 are added to the fifth embodiment of FIG. 11.

As shown in FIG. 23, the insulating oxygen barrier film 35A is formed between the conductive oxygen barrier film 13 and the buffer layer 14A, and the insulating oxygen barrier film 35B is formed between the conductive oxygen barrier film 13 and the buffer layer 14B. The insulating oxygen barrier film 36 is formed on the top and side surfaces of the upper electrode 17, the side surfaces of the ferroelectric film 16, the side surfaces of the lower electrode 15, the side surfaces of the buffer layers 14A and 14B, the side surfaces of the insulating oxygen barrier films 35A and 35B, the side surfaces of the conductive oxygen barrier film 13, and on the interlayer insulation film 11. In other words, the insulating oxygen barrier film 36 is formed to cover the ferroelectric capacitor arranged on the interlayer insulation film 11. The other constituent elements and advantage shown in FIG. 22 are the same as those of the fifth embodiment shown in FIG. 11.

Next, an example of applying the structure of the tenth embodiment shown in FIG. 23 to a TC-parallel unit serial-connection type ferroelectric memory will be explained.

FIG. 24 is a cross-sectional view showing the TC-parallel unit serial-connection type ferroelectric memory, according to the tenth embodiment.

In the ninth embodiment of FIG. 24, the insulating oxygen barrier films 35A, 35B and 36 are added to the fifth embodiment of FIG. 12.

As shown in FIG. 24, the insulating oxygen barrier film 35A is formed between the conductive oxygen barrier film 13 and the buffer layer 14A, and the insulating oxygen barrier film 35B is formed between the conductive oxygen barrier film 13 and the buffer layer 14B. Moreover, the insulating oxygen barrier film 36 is formed on the top and side surfaces of the upper electrodes 17A and 17B, the side surfaces of the ferroelectric film 16, the side surfaces of the lower electrode 15, the side surfaces of the buffer layers 14A and 14B, the side surfaces of the insulating oxygen barrier films 35A and 35B, and the side surfaces of the conductive oxygen barrier film 13, and on the interlayer insulation film 11. In other words, the insulating oxygen barrier film 36 is formed to cover the first and second ferroelectric capacitors arranged on the interlayer insulation film 11. The other constituent elements and advantage shown in FIG. 24 are the same as those of the fifth embodiment shown in FIG. 12.

In the above-described embodiments, the characteristic of shutting out penetration of oxygen, in the conductive oxygen barrier film 13, the insulating oxygen barrier films 35A and 3.5B, and the insulating oxygen barrier film 36 has been explained. However, if the insulating oxygen barrier films 35A, 35B and 36 have the characteristic of shutting out penetration of oxygen, the conductive oxygen barrier film 13 does not need to have this characteristic. Thus, the conductive oxygen barrier film 13 may be formed of the materials including platinum (Pt).

### Eleventh Embodiment

Next, a method of manufacturing the semiconductor device including the ferroelectric memory according to the first to fifth embodiments of the present invention, will be explained as a eleventh embodiment thereof.

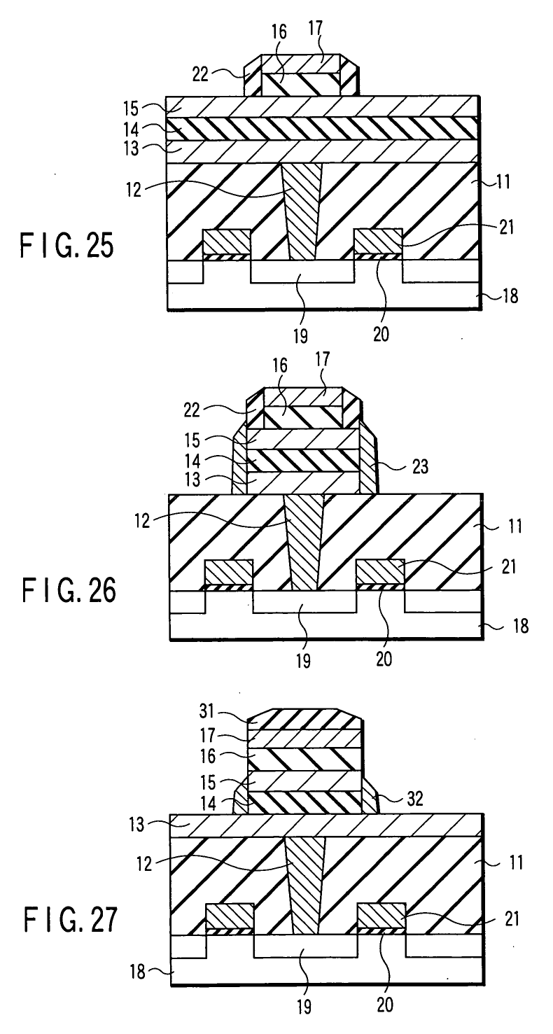

First, a method of manufacturing the semiconductor device including the ferroelectric memory according to the first embodiment as shown in FIG. 2 will be explained. FIGS. 25 and 26 are cross-sectional views showing steps in the method of manufacturing the semiconductor device including the ferroelectric memory according to the first embodiment.

As shown in FIG. 25, a cell transistor including the gate insulation film 20, the gate electrode 21 and the source/drain regions 19 is formed on the silicon semiconductor substrate 18. The interlayer insulation film 11 is formed on the semiconductor substrate 18. A hole is formed in the interlayer insulation film 11 on the source/drain regions 19 by the RIE (reactive ion etching). This hole is filled with a conductive material to form the contact plug 12 electrically connected to the source/drain regions 19.

Films which are to be the conductive oxygen barrier film 13, the buffer layer 14, the lower electrode 15, the ferroelectric film 16 and the upper electrode 17 are formed in order, on the contact plug 12 and interlayer insulation film 11. Subsequently, the films which are to be the upper electrode 17 and the ferroelectric film 16 are processed by patterning and the upper electrode 17 and the ferroelectric film 16 are thereby formed as shown in FIG. 25.

A film which is to be the sidewall insulation films 22 is formed or, for example, SiO₂ or Al₂O₃ is deposited on the top and side surfaces of the upper electrode 17, the side surfaces of the ferroelectric film 16, and the film which is to be the lower electrode 15. Subsequently, the film which is to be the sidewall insulation films 22 is subjected to anisotropic etching by the RIE and the sidewall insulation films 22 are thereby formed on the side surfaces of the upper electrode 17 and the side surfaces of the ferroelectric film 16.

Next, the films which are to be the lower electrode 15, the buffer layer 14, and the conductive oxygen barrier film 13 are subjected to patterning by self-aligning using the sidewall insulation films 22 as masks and the lower electrode 15, the buffer layer 14, and the conductive oxygen barrier film 13 are thereby formed as shown in FIG. 26. After that, a film which is to be the sidewall conductive films 23 is formed or, for example, Pt is deposited on the upper electrode 17, the sidewall insulation films 22, the side surfaces of the lower electrode 15, the side surfaces of the buffer layer 14, the side surfaces of the conductive oxygen barrier film 13, and the interlayer insulation film 11. Subsequently, the film which is to be the sidewall conductive films 23 is subjected to isotropic etching in the manner such as the RIE or the like and the sidewall conductive films 23 are thereby formed on the side surfaces of the lower electrode 15, the side surfaces of the buffer layer 14, and the side surfaces of the conductive oxygen barrier film 13.

After that, the interlayer insulation film 24 is formed in the structure shown in FIG. 26 and the hole is formed in the interlayer insulation film 24 on the upper electrode 17 in the manner such as the RIE or the like, as shown in FIG. 2. The conductive material is embedded in the hole and the contact plug 25 electrically connected to the upper electrode 17 is thereby formed. Moreover, the wiring layer 26 is formed on the contact plug 25. Thus, the semiconductor device shown in FIG. 2 can be produced.

In this manufacturing method, the lithography needs only to be performed at one time during the patterning of the film which is to be the upper electrode 17 and the film which is to be the ferroelectric film 16. The manufacturing method can be therefore made simpler. Furthermore, the sidewall conductive films 23 is formed on the side surfaces of the lower electrode 15, the side surfaces of the buffer layer 14, and the side surfaces of the conductive oxygen barrier film 13 after the sidewall insulation films 22 have been formed on the side surfaces of the upper electrode 17 and the side surfaces of the ferroelectric film 16. Electric short between the upper electrode 17 and the lower electrode 15 caused by the sidewall conductive films 23 can be therefore prevented.

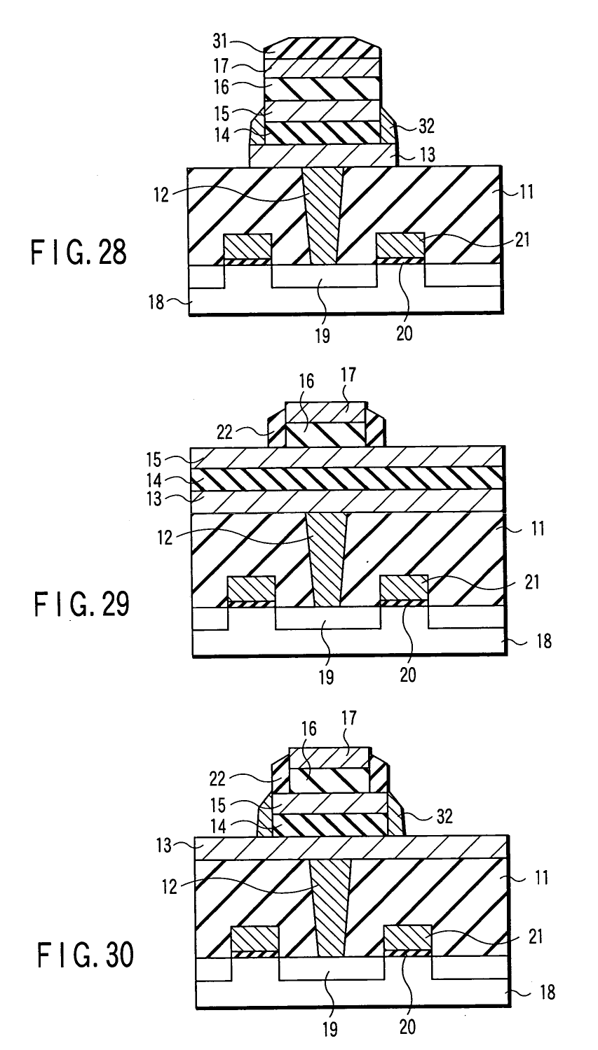

Next, a method of manufacturing the semiconductor device including the ferroelectric memory according to the second embodiment as shown in FIG. 4, will be explained. FIGS. 27 and 28 are cross-sectional views showing steps in the method of manufacturing the semiconductor device including the ferroelectric memory according to the second embodiment.

The cell transistor, the interlayer insulation film 11 and the contact plug 12 are formed in the same manufacturing method as that explained with reference to FIG. 25.

After that, films which are to be the conductive oxygen barrier film 13, the buffer layer 14, the lower electrode 15, the ferroelectric film 16, the upper electrode 17, and the insulation film 31 are formed in order, on the contact plug 12 and the interlayer insulation film 11. Subsequently, the films which are to be the insulation film 31, the upper electrode 17, the ferroelectric film 16 and the lower electrode 15, are processed by patterning. The upper electrode 17, the ferroelectric film 16, the lower electrode 15, and the buffer layer 14 are thereby formed as shown in FIG. 27.

A film which is to be the sidewall conductive films 32 is formed or, for example, Pt is deposited on the insulation film 31, the side surfaces of the upper electrode 17, the side surfaces of the ferroelectric film 16, the side surfaces of the lower electrode 15, the side surfaces of the buffer layer 14, and the film which is to be the conductive oxygen barrier film 13. Subsequently, the film which is to be the sidewall conductive films 32 is subjected to isotropic etching in the manner such as the RIE or the like. The sidewall conductive films 32 are thereby formed on the side surfaces of the lower electrode 15, the side surfaces of the buffer layer 14, and the top surface of the film which is to be the conductive oxygen barrier film 13, as shown in FIG. 27. The film which is to be the conductive oxygen barrier film 13 is processed by patterning using the sidewall conductive films 32 as masks. The conductive oxygen barrier film 13 is thereby formed as shown in FIG. 28.

After that, the interlayer insulation film 24 is formed in the structure shown in FIG. 28 and the hole is formed in the interlayer insulation film 24 and the insulation film 31 on the upper electrode 17 in the manner such as the RIE or the like, as shown in FIG. 4. The conductive material is embedded in the hole and the contact plug 25 electrically connected to the upper electrode 17 is thereby formed. Moreover, the wiring layer 26 is formed on the contact plug 25. Thus, the semiconductor device shown in FIG. 4 can be produced.

In this manufacturing method, the lithography needs only to be performed at one time during the patterning of the insulation film 31, the film which is to be the upper electrode 17, the film which is to be the ferroelectric film 16, the film which is to be the lower electrode 15, and the film which is to be the buffer layer 14. The manufacturing method can be therefore made simpler. Furthermore, the area of the ferroelectric capacitor can be made greater than that of the ferroelectric capacitor shown in FIG. 2.

Next, a method of manufacturing the semiconductor device including the ferroelectric memory according to the third embodiment as shown in FIG. 7, will be explained. FIGS. 29 to 31 are cross-sectional views showing steps in the method of manufacturing the semiconductor device including the ferroelectric memory according to the third embodiment.

The cell transistor, the interlayer insulation film 11 and the contact plug 12 are formed in the same manufacturing method as that explained with reference to FIG. 25.

After that, films which are to be the conductive oxygen barrier film 13, the buffer layer 14, the lower electrode 15, the ferroelectric film 16, and the upper electrode 17 are formed in order, on the contact plug 12 and the interlayer insulation film 11. Subsequently, the films which are to be the upper electrode 17 and the ferroelectric film 16 are processed by patterning. The upper electrode 17 and the ferroelectric film 16 are thereby formed as shown in FIG. 29.

A film which is to be the sidewall insulation films 22 is formed on the top and side surfaces of the upper electrode 17, the side surfaces of the ferroelectric film 16, and the film which is to be the lower electrode 15. Subsequently, the film which is to be the sidewall insulation films 22 is subjected to isotropic etching in the manner such as the RIE or the like. The sidewall insulation films 22 are thereby formed on the side surfaces of the upper electrode 17 and the side surfaces of the ferroelectric film 16 as shown in FIG. 29.

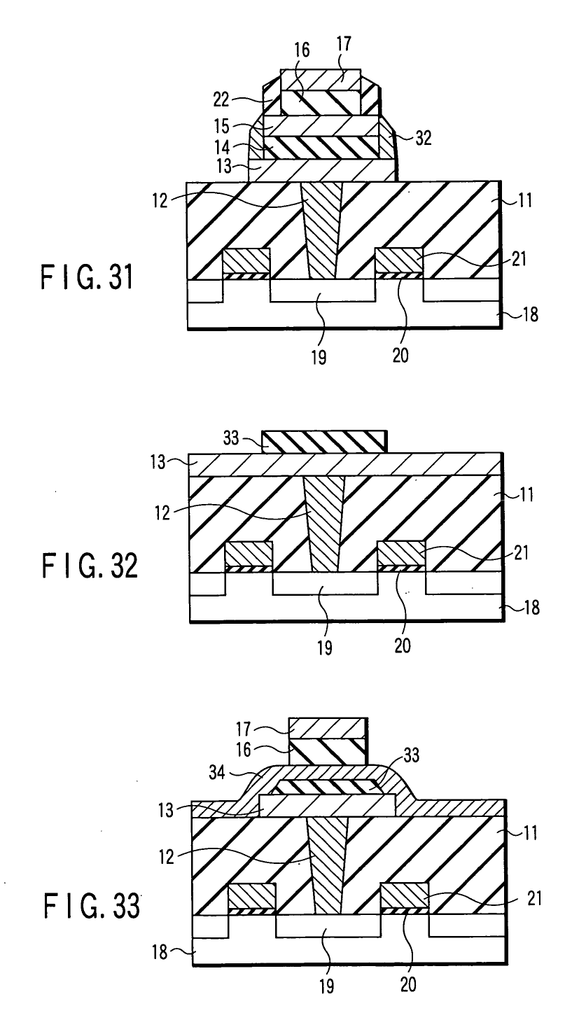

Next, the film which is to be the lower electrode 15 and the film which is to be the buffer layer 14 are processed by patterning using the sidewall insulation films 22 as masks. The lower electrode 15 and the buffer layer 14 are thereby formed as shown in FIG. 30. After that, a film which is to be the sidewall conductive films 32 is formed on the upper electrode 17, the sidewall insulation films 22, the side surfaces of the lower electrode 15, the side surfaces of the buffer layer 14, and the conductive oxygen barrier film 13. Subsequently, the film which is to be the sidewall conductive films 32 is subjected to isotropic etching in the manner such as the RIE or the like. The sidewall conductive films 32 are thereby formed on the side surfaces of the lower electrode 15 and the side surfaces of the buffer layer 14. Furthermore, the film which is to be the conductive oxygen barrier film 13 is processed by patterning using the sidewall conductive films 32 as masks. The conductive oxygen barrier film 13 is thereby formed as shown in FIG. 31.

After that, the interlayer insulation film 24 is formed in the above structure and the hole is formed in the interlayer insulation film 24 on the upper electrode 17 in the manner such as the RIE or the like, as shown in FIG. 7. The conductive material is embedded in the hole and the contact plug 25 electrically connected to the upper electrode 17 is thereby formed. Moreover, the wiring layer 26 is formed on the contact plug 25. Thus, the semiconductor device shown in FIG. 7 can be produced.

In this manufacturing method, the lithography needs only to be performed at one time during the patterning of the film which is to be the upper electrode 17 and the film which is to be the ferroelectric film 16. The manufacturing method can be therefore made simpler. Furthermore, contact resistance between the sidewall conductive films 32 and the conductive oxygen barrier film 13 can be restricted in the sidewall conductive films 32 which make electric connection between the conductive oxygen barrier film 13 and the lower electrode 15.

Next, a method of manufacturing the semiconductor device including the ferroelectric memory according to the fourth embodiment as shown in FIG. 9, will be explained. FIGS. 32 to 34 are cross-sectional views showing steps in the method of manufacturing the semiconductor device including the ferroelectric memory according to the fourth embodiment.

The cell transistor, the interlayer insulation film 11 and the contact plug 12 are formed in the same manufacturing method as that explained with reference to FIG. 25.

After that, films which are to be the conductive oxygen barrier film 13 and the buffer layer 33 are formed in order, on the contact plug 12 and the interlayer insulation film 11. Subsequently, the film which is to be the buffer layer 33 is processed by patterning. The buffer layer 33 having a predetermined shape is thereby formed as shown in FIG. 32.

Next, the film which is to be the conductive oxygen barrier film 13 is processed by patterning using the buffer layer 33 as a mask. The conductive oxygen barrier film 13 is thereby formed, and the peripheral portion on the top surface of the conductive oxygen barrier film 13 is exposed by removing side portions of the buffer layer 33 in a lateral direction, as shown in FIG. 33.

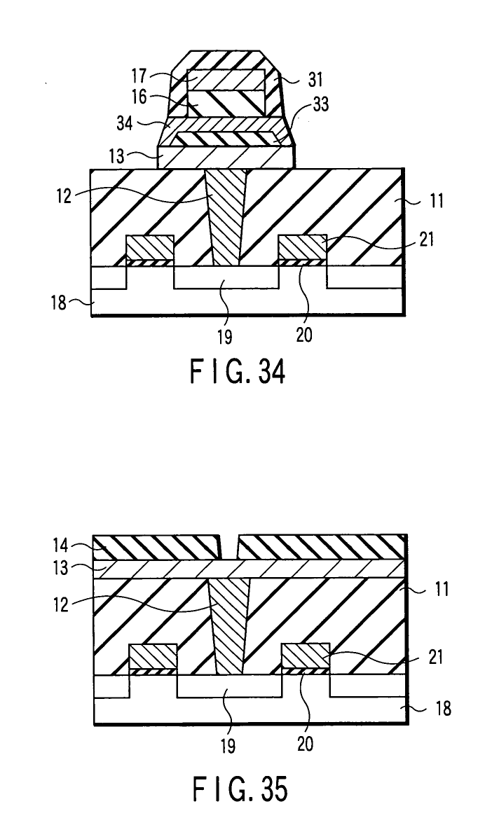

Subsequently, films which are to be the lower electrode 34, the ferroelectric film 16 and the upper electrode 17 are deposited in order, on the buffer layer 33, the peripheral portion on the top surface of the conductive oxygen barrier film 13 and the interlayer insulation film 11. The films which are to be the upper electrode 17 and the ferroelectric film 16 are processed by patterning. The upper electrode 17 and the ferroelectric film 16 are thereby formed as shown in FIG. 33. Furthermore, the film which is to be the insulation film 31 is deposited on the top and side surfaces of the upper electrode 17, the side surfaces of the ferroelectric film 16, and the film which is to be the lower electrode 15. Subsequently, the top surface of the film which is to be the insulation film 31 is protected by a masking material and subjected to isotropic etching in the manner such as the RIE or the like. The insulation film 31 is thereby formed on the top and side surfaces of the upper electrode 17, the side surfaces of the ferroelectric film 16, and the lower electrode 34, and the lower electrode 34 on the top surface of the interlayer insulation film 11 is removed, as shown in FIG. 34.

After that, the interlayer insulation film 24 is formed in the above-described structure and the hole is formed in the interlayer insulation film 24 on the upper electrode 17 in the manner such as the RIE or the like, as shown in FIG. 9. The conductive material is embedded in the hole and the contact plug 25 electrically connected to the upper electrode 17 is thereby formed. Moreover, the wiring layer 26 is formed on the contact plug 25. Thus, the semiconductor device shown in FIG. 9 can be produced.

In this manufacturing method, the sidewall conductive films making electric connection between the conductive oxygen barrier film 13 and the lower electrode 34 do not need to be formed. The manufacturing method can be therefore made simpler.

Next, a method of manufacturing the semiconductor device including the ferroelectric memory according to the fifth embodiment as shown in FIG. 11, will be explained.

FIGS. 35 to 37 are cross-sectional views showing steps in the method of manufacturing the semiconductor device including the ferroelectric memory according to the fifth embodiment.

The cell transistor, the interlayer insulation film 11 and the contact plug 12 are formed in the same manufacturing method as that explained with reference to FIG. 25.

After that, films which are to be the conductive oxygen barrier film 13 and the buffer layer 14 are formed in order, on the contact plug 12 and the interlayer insulation film 11. Subsequently, the hole is formed in the film which is to be the buffer layer 14 in the manner such as the RIE or the like, such that the hole reaches the film which is to be the conductive oxygen barrier film 13.

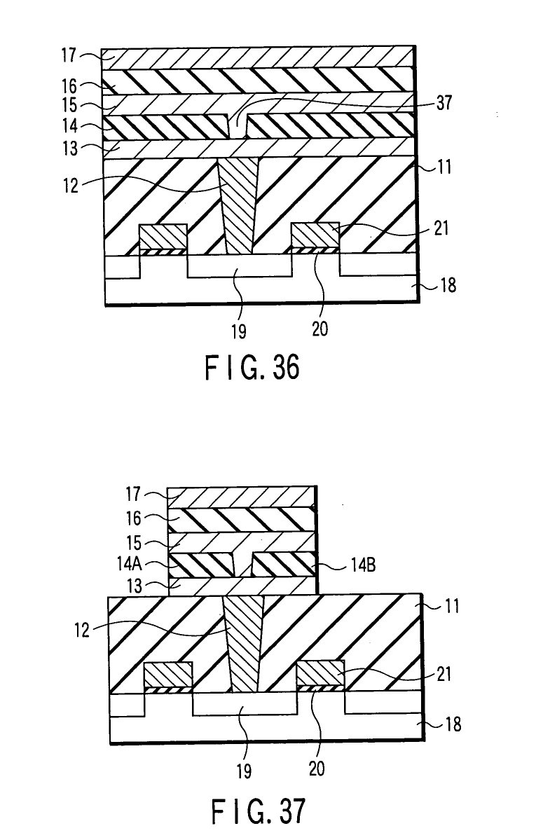

Next, the film which is to be the lower electrode 15 is formed on the buffer layer 14 as shown in FIG. 36. At this time, the film which is to be the lower electrode 15 is embedded in the hole formed in the buffer layer 14 to form the contact plug 37. The contact plug 37 makes electric connection between the lower electrode 15 and the conductive oxygen barrier film 13. The films which are to be the ferroelectric film 16 and the upper electrode 17 are further formed in order, on the film which is to be the lower electrode 15.

Subsequently, the film which are to be the upper electrode 17, the ferroelectric film 16, the lower electrode 15, the buffer layer 14 and the conductive oxygen barrier film 13 are processed by patterning. As shown in FIG. 37, the upper electrode 17, the ferroelectric film 16, the lower electrode 15, the buffer layer 14 and the conductive oxygen barrier film 13 are thereby formed.

After that, the interlayer insulation film 24 is formed in the above-described structure and the hole is formed in the interlayer insulation film 24 on the upper electrode 17 in the manner such as the RIE or the like, as shown in FIG. 11. The conductive material is embedded in the hole and the contact plug 25 electrically connected to the upper electrode 17 is thereby formed. Moreover, the wiring layer 26 is formed on the contact plug 25. Thus, the semiconductor device shown in FIG. 11 can be produced.

In this manufacturing method, the sidewall conductive films making electric connection between the conductive oxygen barrier film 13 and the lower electrode 15 do not need to be formed. The manufacturing method can be therefore made simpler. Furthermore, the area of the ferroelectric capacitor can be made greater than that of the ferroelectric capacitor shown in FIG. 9.

The embodiments of the present invention can provide a semiconductor device capable of having an optimum conductive oxygen barrier film and a preferable ferroelectric capacitor characteristic by forming a buffer layer between a conductive oxygen barrier film and a lower electrode of a ferroelectric capacitor, and a manufacturing method of the semiconductor device.

The present invention is not only limited to each of the above-described embodiments, but can be limited to any combination of the embodiments. Furthermore, the embodiments contain various aspects of the invention. Thus, various aspects of the invention can also be extracted from any appropriate combination of a plurality of constituent elements disclosed in the embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a transistor formed on a semiconductor substrate, including a source/drain region;
a plug electrode formed on the source/drain region;
a conductive film formed on the plug electrode;
a first insulation film formed on the conductive film;
a lower electrode formed on the first insulation film, the lower electrode being electrically connected to the conductive film formed on the plug electrode;
a ferroelectric film formed on the lower electrode; and
an upper electrode formed on the ferroelectric film.

2. The semiconductor device according to claim 1, further comprising a second insulation film formed between the first insulation film and the lower electrode.

3. The semiconductor device according to claim 1, further comprising:
first sidewall insulation films formed on side surfaces of the upper electrode and side surfaces of the ferroelectric film; and
second sidewall conductive films formed on side surfaces of the lower electrode, side surfaces of the first insulation film, and side surfaces of the conductive film.

4. The semiconductor device according to claim 1, further comprising sidewall conductive films formed on side surfaces of the lower electrode, side surfaces of the first insulation film, and a top surface of the conductive film.

5. The semiconductor device according to claim 1, further comprising:
third sidewall insulation films formed on side surfaces of the upper electrode and side surfaces of the ferroelectric film; and
fourth sidewall conductive films formed on side surfaces of the lower electrode, side surfaces of the first insulation film, and a top surface of the conductive film.

6. The semiconductor device according to claim 1, wherein the lower electrode is in contact with a peripheral portion of the top surface of the conductive film.

7. The semiconductor device according to claim 1, further comprising a plug electrode which is embedded in a hole formed in the first insulation film and which makes electric connection between the conductive film and the lower electrode.

8. The semiconductor device according to claim 1, further comprising a third insulation film formed along top and side surfaces of the upper electrode, side surfaces of the ferroelectric film, side surfaces of the lower electrode, side surfaces of the first insulation film, and side surfaces of the conductive film.

9. The semiconductor device according to claim 1, wherein a ferroelectric capacitor comprises the lower electrode, the ferroelectric film, and the upper electrode.

10. A semiconductor device comprising:
a first source/drain region formed on a surface region of a semiconductor substrate;
a second source/drain region formed on the surface region of the semiconductor substrate, separately from the first source/drain region;
a first gate insulation film formed on the semiconductor substrate between the first source/drain region and the second source/drain region;
a first gate electrode formed on the first gate insulation film;
an interlayer insulation film formed on the semiconductor substrate so as to cover the first source/drain region, the second source/drain region, and the first gate electrode;
a plug electrode formed in the interlayer insulation film on the first source/drain region and electrically connected to the first source/drain region;
a conductive film formed on the plug electrode and electrically connected to the plug electrode;
a first insulation film formed on the conductive film;
a lower electrode formed on the first insulation film;
a first ferroelectric film and a second ferroelectric film both formed on the lower electrode;
a first upper electrode formed on the first ferroelectric film and electrically connected to the second source/drain region; and
a second upper electrode formed on the second ferroelectric film.

11. The semiconductor device according to claim 10, wherein a first ferroelectric capacitor comprises the lower electrode, the first ferroelectric film and the first upper electrode and a second ferroelectric capacitor comprises the lower electrode, the second ferroelectric film and the second upper electrode.

12. The semiconductor device according to claim 10, further comprising:
a third source/drain region formed on the surface region of the semiconductor substrate, separately from the first source/drain region, and electrically connected to the second upper electrode;
a second gate insulation film formed on the semiconductor substrate between the first source/drain region and the third source/drain region; and
a second gate electrode formed on the second gate insulation film.

13. A method of manufacturing a semiconductor device, comprising:
forming a transistor including a gate insulation film, a gate electrode and a source/drain region on a semiconductor substrate;
forming an interlayer insulation film on the semiconductor substrate on which the transistor is formed;
forming a contact plug electrically connected to the source/drain region, in the interlayer insulation film on the source/drain region;
forming a conductive film on the contact plug and the interlayer insulation film;
forming a first insulation film on the conductive film;
forming a lower electrode on the first insulation film;
forming a ferroelectric film on the lower electrode; and
forming an upper electrode on the ferroelectric film.

14. The method according to claim 13, further comprising:
forming sidewall insulation films on side surfaces of the upper electrode and side surfaces of the ferroelectric film;
processing the lower electrode, the first insulation film and the conductive film by self-aligning using the sidewall insulation films as masks; and
forming sidewall conductive films on side surfaces of the lower electrode, the first insulation film and the conductive film processed by the self-aligning.

15. The method according to claim 13, further comprising:
processing the side surfaces of the upper electrode, the ferroelectric film, the lower electrode and the first insulation film such that the side surfaces thereof correspond to each other; and
forming sidewall conductive films on the corresponding side surfaces of the lower electrode and the first insulation film, and a top surface of the conductive film.

16. The method according to claim 13, further comprising:
forming sidewall insulation films on side surfaces of the upper electrode and side surfaces of the ferroelectric film;
processing the lower electrode and the first insulation film by self-aligning using the sidewall insulation films as masks; and
forming sidewall conductive films on the side surfaces of the lower electrode and the first insulation film processed by the self-aligning, and a top surface of the conductive film.

17. A method of manufacturing a semiconductor device, comprising:
forming a contact plug in an interlayer insulation film on a semiconductor substrate;
forming a conductive film on the contact plug and the interlayer insulation film;
forming a first insulation film on the conductive film;
forming a second insulation film on the first insulation film;
forming a lower electrode on the second insulation film;
forming a ferroelectric film on the lower electrode; and
forming an upper electrode on the ferroelectric film.

18. A method of manufacturing a semiconductor device, comprising:
forming a contact plug in an interlayer insulation film on a semiconductor substrate;
forming a conductive film on the contact plug and the interlayer insulation film;
forming a first insulation film having a predetermined shape on the conductive film;
processing the conductive film by using the first insulation film as a mask, and removing side portions of the first insulation film in a lateral direction to expose a peripheral portion of a top surface of the conductive film;
forming a lower electrode on the first insulation film and the peripheral portion of the top surface of the conductive film;
forming a ferroelectric film on the lower electrode; and
forming an upper electrode on the ferroelectric film.

19. A method of manufacturing a semiconductor device, comprising:
forming a contact plug in an interlayer insulation film on a semiconductor substrate;
forming a conductive film on the contact plug and the interlayer insulation film;
forming a first insulation film on the conductive film;
forming a hole which reaches the conductive film, on the first insulation film;
forming a lower electrode on the first insulation film and filling the hole formed on the first insulation film with a material of the lower electrode to form a contact plug;
forming a lower electrode on the first insulation film;
forming a ferroelectric film on the lower electrode; and
forming an upper electrode on the ferroelectric film.

20. The method according to claim 13, further comprising forming a third insulation film along top and side surfaces of the upper electrode, side surfaces of the ferroelectric film, side surfaces of the lower electrode, side surfaces of the first insulation film, and side surfaces of the conductive film.
